(19) United States
(12) Patent Application Publication
(10) Pub. No.: US 2025/0017069 A1
(43) Pub. Date: Jan. 9, 2025

(54) TOUCH-CONTROL STRUCTURE, TOUCH-CONTROL DISPLAY PANEL AND DISPLAY APPARATUS

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Yipeng CHEN, Beijing (CN); Hui LU, Beijing (CN); Ling SHI, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/705,621

(22) PCT Filed: May 19, 2023
(86) PCT No.: PCT/CN2023/095167

§ 371 Date: Apr. 29, 2024

(30) Foreign Application Priority Data
May 31, 2022 (CN) 202210612998.5

(51) Int. Cl. H10K 59/35; G06F 3/041; G06F 3/044; H10K 59/122; H10K 59/40; H10K 59/80

(52) U.S. Cl. CPC H10K 59/353; G06F 3/0412; G06F 3/0445; G06F 3/0446; H10K 59/122; H10K 59/40; H10K 59/8792; G06F 2203/04112; H10K 59/351

(57) ABSTRACT

A display substrate is provided, the display substrate has a display region and includes a base substrate, sub-pixels, data lines, and first signal lines; each of at least part of the sub-pixels includes a pixel driving circuit and a light-emitting device; the data lines are in a first metal layer, the first signal lines are in a second metal layer; in a first display region, a plurality of first signal lines extend in a first direction, the first display region includes first compensation patterns, the first electrode is on a side of the first signal lines and the first compensation patterns away from the base substrate, an orthographic projection of at least one first compensation pattern on the base substrate at least partially overlaps with an orthographic projection of the first electrode of a light-emitting device of at least one sub-pixel on the base substrate.

### CROSS REFERENCE TO RELATED APPLICATIONS

For all purposes, the present application claims priority of China Patent application No. 202210612998.5 filed on May 31, 2022, the content of which is incorporated in its entirety as part of the embodiments of the present disclosure by reference herein.

### TECHNICAL FIELD

At least one embodiment of the present disclosure relates to a touch structure, a touch display panel, and a display apparatus.

### BACKGROUND

At present, in the display field, an increasing number of people are expressing more requirements on improving the optical efficiency of display apparatuses and reducing power consumption to increase hours of use and avoid worrying about the power consumption. Meanwhile, people also hope that the display apparatuses may have vivid and bright colors.

### SUMMARY

At least one embodiment of the present disclosure provides a touch structure, a touch display panel, and a display apparatus.

At least one embodiment of the present disclosure provides a touch structure, including: a first insulating layer; a first touch layer located on the first insulating layer; a second insulating layer located on a side of the first touch layer facing away from the first insulating layer; and a second touch layer located on a side of the second insulating layer facing away from the first touch layer; the first touch layer includes a plurality of first touch electrodes and a plurality of first touch lines; the second touch layer includes a plurality of second touch electrodes and a plurality of second touch lines; the plurality of first touch electrodes and the plurality of second touch electrodes are intersected with each other and are insulated from each other; each of the plurality of first touch electrodes is of a mesh structure, and each of the plurality of second touch electrodes is of the mesh structure; mesh lines of two adjacent first touch electrodes are disconnected and mesh lines of two adjacent second touch electrodes are disconnected; and no via hole is arranged in a region of the second insulating layer that corresponds to the plurality of first touch electrodes and the plurality of second touch electrodes.

For example, the second touch layer further includes a third touch line and the first touch layer further includes a fourth touch line, the third touch line and the first touch line are connected through a first via hole passing through the second insulating layer to form a first lead, and the fourth touch line and the second touch line are connected through a second via hole passing through the second insulating layer to form a second lead.

For example, the first via hole and the second via hole are located in a periphery of an effective region in which the plurality of first touch electrodes and the plurality of second touch electrodes are disposed, and the touch structure further includes a ground line, the ground line is grounded, and the ground line is located between the first lead and the second lead at a position close to a bonding region.

For example, the first touch layer further includes a plurality of first dummy electrodes, each of the plurality of first dummy electrodes and the first touch electrode are insulated from each other, the second touch layer further includes a plurality of second dummy electrodes, each of the plurality of second dummy electrodes and the second touch electrode are insulated from each other, the first dummy electrode includes a plurality of first dummy sub-electrodes and the second dummy electrode includes a plurality of second dummy sub-electrodes, the plurality of first dummy sub-electrodes are spaced apart from each other, and the plurality of second dummy sub-electrodes are spaced apart from each other, the first dummy electrode is of the mesh structure, and a mesh line of the first touch electrode is disconnected from a mesh line of the first dummy electrode, and the second dummy electrode is of the mesh structure, and a mesh line of the second touch electrode is disconnected from a mesh line of the second dummy electrode.

For example, the first touch electrode includes a plurality of first touch portions that are connected to each other, and the second touch electrode includes a plurality of second touch portions that are connected to each other.

For example, the first touch layer further includes a plurality of third dummy electrodes and the second touch layer further includes a plurality of fourth dummy electrodes, each of the plurality of third dummy electrodes is located between two adjacent first touch portions of the first touch electrode, and each of the plurality of fourth dummy electrodes is located between two adjacent second touch portions of the second touch electrode, the third dummy electrode includes a plurality of third dummy sub-electrodes and the fourth dummy electrode includes a plurality of fourth dummy sub-electrodes, the plurality of third dummy sub-electrodes are spaced apart from each other, and the plurality of fourth dummy sub-electrodes are spaced apart from each other.

For example, the touch structure further includes a third insulating layer, the third insulating layer is located on a side of the second touch layer facing away from the second insulating layer, and at least two of the first insulating layer, the second insulating layer, and the third insulating layer include an organic layer.

For example, one of the first touch electrode and the second touch electrode extends in a first direction, the other one of the first touch electrode and the second touch electrode extends in a second direction, and the first direction intersects the second direction, the first touch electrode is connected to at least one of the plurality of first touch lines, and the first touch electrode and the first touch line connected thereto are of an integrated structure, the second touch electrode is connected to at least one of the plurality of second touch lines, and the second touch electrode and the second touch line connected thereto are of an integrated structure.

At least one embodiment of the present disclosure further provides a touch display panel, including a display structure and a touch structure, the display structure includes a plurality of sub-pixels that include a plurality of light emitting elements; the touch structure includes: a first insulating layer; a first touch layer located on the first insulating layer; a second insulating layer located on a side of the first touch layer facing away from the first insulating layer; and a second touch layer located on a side of the second insulating layer facing away from the first touch layer, the first touch layer includes a plurality of first touch electrodes and a plurality of first touch lines; the second touch layer includes a plurality of second touch electrodes and a plurality of second touch lines; the plurality of first touch electrodes and the plurality of second touch electrodes are intersected with each other and are insulated from each other; each of the plurality of first touch electrodes is of a mesh structure, and each of the plurality of second touch electrodes is of the mesh structure; mesh lines of two adjacent first touch electrodes are disconnected and mesh lines of two adjacent second touch electrodes are disconnected, and no via hole is arranged in a region of the second insulating layer that corresponds to the plurality of first touch electrodes and the plurality of second touch electrodes.

For example, the touch display panel further includes: a base substrate; and an encapsulation layer, the encapsulation layer is located on a side of the plurality of light emitting elements facing away from the base substrate, and configured to encapsulate the plurality of light emitting elements; and the touch structure is located on a side of the encapsulation layer facing away from the plurality of light emitting elements.

For example, the touch display panel further includes an anti-reflection layer, the anti-reflection layer is located on a side of the touch structure facing away from the base substrate.

For example, the anti-reflection layer includes a black matrix, orthographic projections of the plurality of first touch electrodes and the plurality of second touch electrodes on the base substrate overlap an orthographic projection of the black matrix on the base substrate.

For example, the anti-reflection layer includes a color filter layer that includes a plurality of color filter units, and an orthographic projection of the plurality of color filter units on the base substrate does not overlap the orthographic projections of the plurality of first touch electrodes and the plurality of second touch electrodes on the base substrate.

For example, the touch display panel further includes a pixel definition layer, the pixel definition layer includes a plurality of openings and a pixel definition portion located between two adjacent openings, and the orthographic projections of the plurality of first touch electrodes and the plurality of second touch electrodes on the base substrate overlap an orthographic projection of the pixel definition portion on the base substrate.

For example, distances of an orthographic projection of at least a portion of mesh lines in the plurality of first touch electrodes and the plurality of second touch electrodes on the base substrate from orthographic projections of two opposite edges of the pixel definition portion on the base substrate are equal or substantially equal.

For example, distances of the orthographic projection of at least a portion of the mesh lines in the plurality of first touch electrodes and the plurality of second touch electrodes on the base substrate from orthographic projections of two opposite edges of the black matrix on the base substrate are equal or substantially equal.

For example, the plurality of sub-pixels include a first sub-pixel, two second sub-pixels, and a third sub-pixel, and the two second sub-pixels are arranged in a first direction, the first sub-pixel and the third sub-pixel are arranged in a second direction, the first direction intersects the second direction, and the mesh lines include a portion located among the first sub-pixel, the two second sub-pixels, and the third sub-pixel and extending in the first direction.

For example, a length of the portion of the mesh lines that extends in the first direction is less than a maximum length of a light emitting region of the first sub-pixel in the first direction and less than a maximum length of a light emitting region of the third sub-pixel in the first direction.

For example, each of the plurality of sub-pixels has a virtual pixel center, an extension direction of a width and an extension direction of a length of the sub-pixel are taken as a width extension direction and a length extension direction of a defining quadrangle, respectively, and the width and the length of the sub-pixel are taken as a width and a length of the defining quadrangle, respectively, and an intersection point of diagonals of the defining quadrangle is taken as the virtual pixel center, the plurality of sub-pixels include a first sub-pixel, second sub-pixels, and a third sub-pixel, the first sub-pixel and the third sub-pixel are arranged alternately in the first direction to form a first pixel group, the second sub-pixels are disposed side by side in the first direction to form a second pixel group, the first sub-pixel and the third sub-pixel are arranged alternately in the second direction to form a third pixel group, the second sub-pixels are disposed side by side in the second direction to form a fourth pixel group, the first pixel group and the second pixel group are arranged alternately in the second direction, and the third pixel group and the fourth pixel group are arranged alternately in the first direction, sequential connecting lines of virtual centers of two first sub-pixels and two third sub-pixels between two adjacent first pixel groups and two adjacent third pixel groups form a second virtual quadrangle, four second virtual quadrangles arranged in an array form a first virtual polygon in such a manner that adjacent edges are shared, and the first sub-pixels and the third sub-pixels are located at vertex angles or edges of the first virtual polygon and alternately distributed clockwise at the vertex angles or the edges of the first virtual polygon, the first virtual polygon has a first virtual point therein, and connecting lines of the first virtual point and the virtual centers of four third sub-pixels on the first virtual polygon divide the first virtual polygon into four virtual isosceles trapezoids.

Embodiments of the present disclosure further provides a display apparatus, including any one of the touch display panels as described above.

### BRIEF DESCRIPTION OF THE DRAWINGS

In order to more clearly illustrate the technical solutions of the embodiments of the present disclosure, the drawings of the embodiments will be briefly described in the following, it is obvious that the described drawings below are only related to some embodiments of the present disclosure and thus are not limitative to the present disclosure.

FIG. 1 is a plan view of a touch structure provided by an embodiment of the present disclosure.

FIG. 2 is a plan view of a touch structure provided by another embodiment of the present disclosure.

FIG. 3 is a plan view of a touch structure provided by another embodiment of the present disclosure.

FIG. 4 is a cross-sectional view of FIG. 3 taken along line A1-A2.

FIG. 5A is a cross-sectional view of FIG. 3 taken along line B1-B2.

FIG. 5B is a cross-sectional view of FIG. 3 taken along line B3-B4.

FIG. 6 is a plan view of a first touch layer in FIG. 3.

FIG. 7 is a plan view of a second touch layer in FIG. 3.

FIG. 8 is a plan view of a touch structure provided by another embodiment of the present disclosure.

FIG. 9A is a plan view of a first touch layer in a touch structure provided by another embodiment of the present disclosure.

FIG. 9B is a plan view of a second touch layer in a touch structure provided by another embodiment of the present disclosure.

FIG. 10A is a partial plan view of a first touch layer in a touch structure provided by another embodiment of the present disclosure.

FIG. 10B is a partial plan view of a second touch layer in a touch structure provided by another embodiment of the present disclosure.

FIG. 11 is a plan view of a touch structure provided by another embodiment of the present disclosure.

FIG. 12 is a plan view of a touch structure provided by an embodiment of the present disclosure.

FIG. 13A is a plan view of a first touch layer in FIG. 12.

FIG. 13B is a plan view of a second touch layer in FIG. 12.

FIG. 14 is a cross-sectional view of FIG. 12 taken along line A3-A4.

FIG. 15A is a cross-sectional view of FIG. 12 taken along line B5-B6.

FIG. 15B is a cross-sectional view of FIG. 12 taken along line B7-B8.

FIG. 15C is a plan view of a first touch layer and a second insulating layer in a touch structure provided by an embodiment of the present disclosure.

FIG. 16A is a partial plan view of a first touch layer in a touch structure provided by another embodiment of the present disclosure.

FIG. 16B is a partial plan view of a second touch layer in a touch structure provided by another embodiment of the present disclosure.

FIG. 17A is a plan view of a touch display panel provided by an embodiment of the present disclosure.

FIG. 17B is a cross-sectional view of FIG. 17A taken along line A5-A6.

FIG. 18A is a cross-sectional view of a touch display panel provided by an embodiment of the present disclosure.

FIG. 18B is a cross-sectional view of a touch display panel provided by an embodiment of the present disclosure.

FIG. 19 is a plan view of mesh lines of light emitting regions and touch electrodes in a touch display panel provided by an embodiment of the present disclosure.

FIG. 20 is a schematic diagram of a pixel circuit and a light emitting element of a sub-pixel in a display panel provided by some embodiments of the present disclosure.

FIG. 21A is a schematic diagram of a film layer structure of an exemplary pixel array.

FIG. 21B is a schematic diagram of a film layer structure of another exemplary pixel array.

FIG. 22 is a schematic diagram of an exemplary pixel array.

FIG. 23 is a schematic diagram of a pixel array according to an embodiment of the present disclosure.

FIG. 24 is a schematic diagram of an arrangement of sub-pixels in a first virtual polygon according to an embodiment of the present disclosure.

FIG. 25 is a schematic diagram of an arrangement of sub-pixels in a second virtual quadrangle in the first virtual polygon of FIG. 24.

FIG. 26 is schematic diagram of an arrangement of sub-pixels in a third virtual quadrangle in the first virtual polygon of FIG. 24.

FIG. 27 is a schematic diagram of an arrangement of sub-pixels in a virtual isosceles trapezoid in the first virtual polygon of FIG. 24.

FIG. 28 is a schematic diagram of an arrangement of sub-pixels in another first virtual polygon according to an embodiment of the present disclosure.

FIG. 29 is a schematic diagram of an arrangement of sub-pixels in another first virtual polygon according to an embodiment of the present disclosure.

FIG. 30 is a schematic diagram of an arrangement of sub-pixels in another first virtual polygon according to an embodiment of the present disclosure.

FIG. 31 is a schematic diagram of an arrangement of sub-pixels in another first virtual polygon according to an embodiment of the present disclosure.

FIG. 32 is a schematic diagram of an arrangement of sub-pixels in another first virtual polygon according to an embodiment of the present disclosure.

FIG. 33 is a schematic diagram of an arrangement of sub-pixels in another first virtual polygon according to an embodiment of the present disclosure.

FIG. 34 is a schematic diagram of an arrangement of sub-pixels in another first virtual polygon according to an embodiment of the present disclosure.

FIG. 35 is a schematic diagram of light emitting regions of sub-pixels in the first virtual polygon of FIG. 34.

FIG. 36 is a schematic diagram of a distribution of sub-pixels in a fourth virtual quadrangle in the first virtual polygon of FIG. 34.

FIG. 37 is a schematic diagram of an arrangement of sub-pixels in another first virtual polygon according to an embodiment of the present disclosure.

FIG. 38 is a schematic diagram of light emitting regions of sub-pixels in the first virtual polygon of FIG. 37.

FIG. 39 is a schematic diagram of an arrangement of sub-pixels in another first virtual polygon according to an embodiment of the present disclosure.

FIG. 40 is a schematic diagram of light emitting regions of sub-pixels in the first virtual polygon of FIG. 39.

FIG. 41 is a schematic diagram of an arrangement of sub-pixels in another first virtual polygon according to an embodiment of the present disclosure.

FIG. 42 is a schematic diagram of a light emitting region of each sub-pixel in the first virtual polygon of FIG. 41.

FIG. 43 is a schematic diagram of another light emitting region of each sub-pixel in the first virtual polygon of FIG. 41.

FIG. 44 is a schematic diagram of an arrangement of sub-pixels in another first virtual polygon according to an embodiment of the present disclosure.

FIG. 45 is a schematic diagram of light emitting regions of sub-pixels in the first virtual polygon of FIG. 44.

### DETAILED DESCRIPTION

In order to make objectives, technical details and advantages of the embodiments of the present disclosure more clearly, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first”, “second”, etc., which are used in the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the described object is changed, the relative position relationship may be changed accordingly.

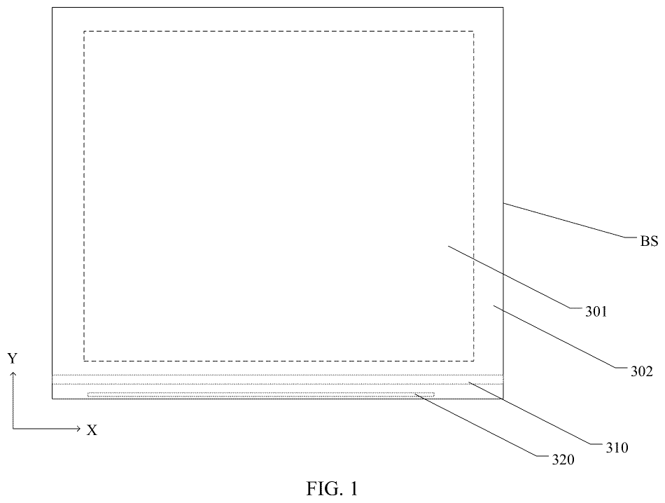

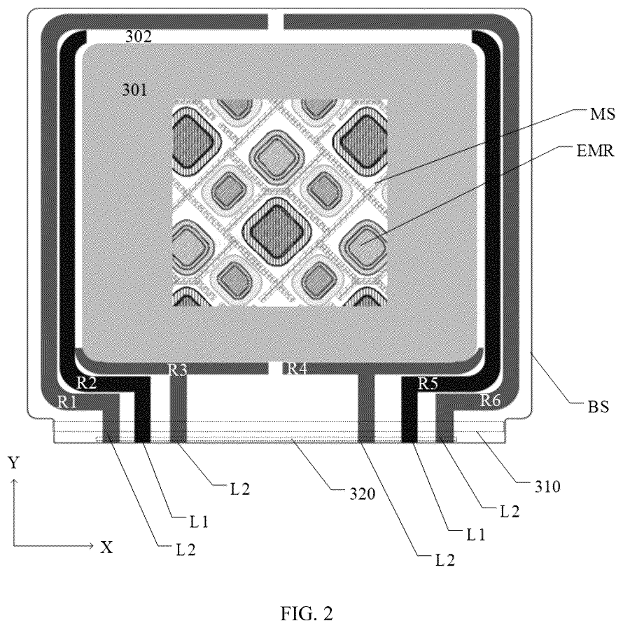

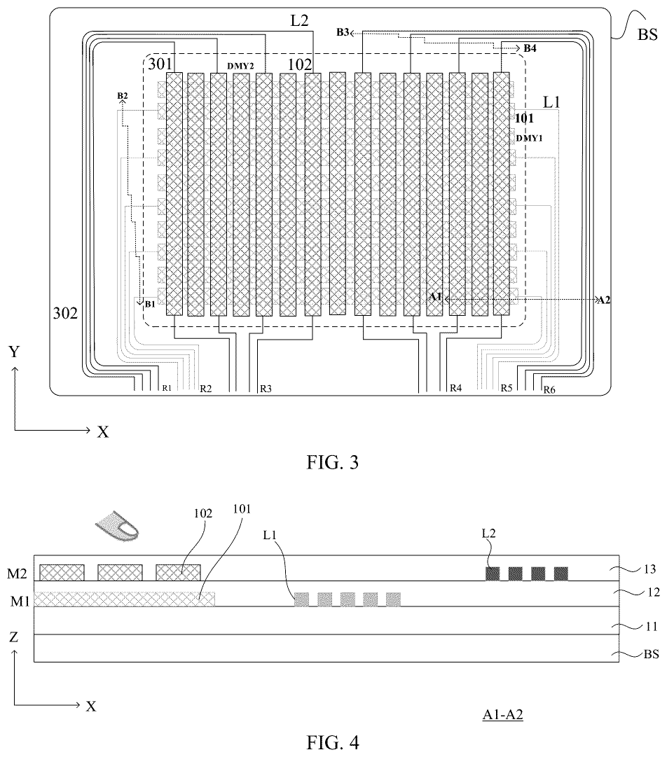

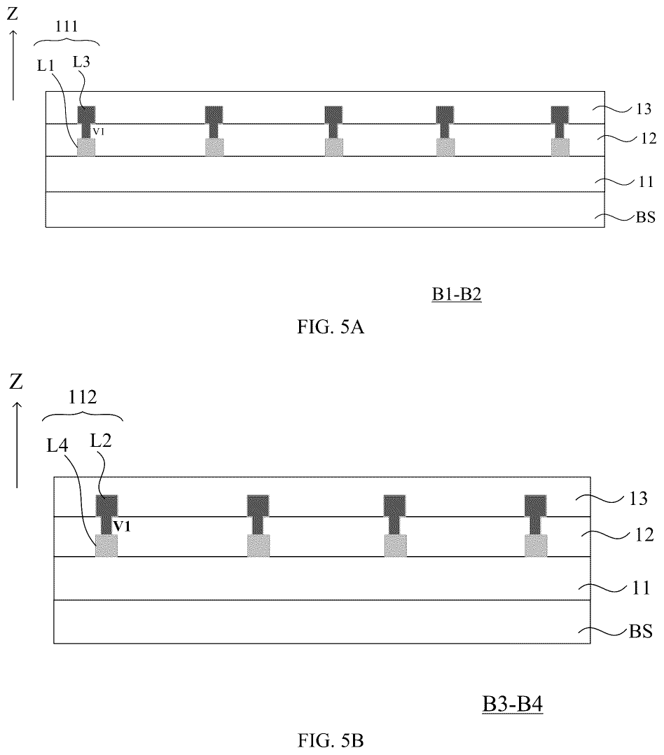

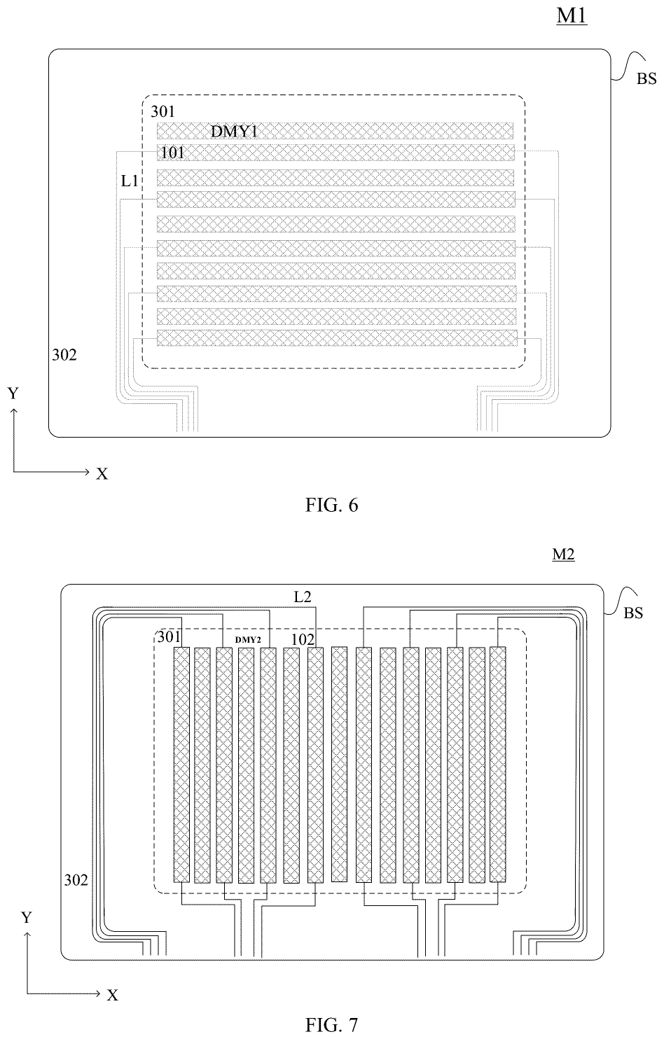

FIG. 1 is a plan view of a touch structure provided by an embodiment of the present disclosure. FIG. 2 is a plan view of a touch structure provided by another embodiment of the present disclosure. FIG. 3 is a plan view of a touch structure provided by another embodiment of the present disclosure. FIG. 4 is a cross-sectional view of FIG. 3 taken along line A1-A2. FIG. 5A is a cross-sectional view of FIG. 3 taken along line B1-B2. FIG. 5B is a cross-sectional view of FIG. 3 taken along line B3-B4. FIG. 6 is a plan view of a first touch layer in FIG. 3. FIG. 7 is a plan view of a second touch layer in FIG. 3.

As shown in FIG. 1 to FIG. 3 and FIG. 6 to FIG. 7, a touch structure provided by the embodiments of the present disclosure includes a first insulating layer 11, a first touch layer M1, a second insulating layer 12, and a second touch layer M2.

As shown in FIG. 4, the first touch layer M1 is located on the first insulating layer 11, the second insulating layer 12 is located on a side of the first touch layer M1 facing away from the first insulating layer 11, and the second touch layer M2 is located on a side of the second insulating layer 12 facing away from the first touch layer M1.

As shown in FIG. 2 to FIG. 3 and FIG. 6 to FIG. 7, the first touch layer M1 includes a plurality of first touch electrodes 101 and a plurality of first touch lines L1, and the second touch layer M2 includes a plurality of second touch electrodes 102 and a plurality of second touch lines L2. The plurality of first touch electrodes 101 and the plurality of second touch electrodes 102 are intersected with each other and are insulated from each other. With reference to FIG. 1 to FIG. 3, the plurality of first touch lines L1 and the plurality of second touch lines L2 are located in a peripheral region 302. As shown in FIG. 2, the plurality of first touch lines L1 and the plurality of second touch lines L2 are collected to a bonding region 320. For example, the plurality of first touch lines L1 and the plurality of second touch lines L2 are connected to a flexible circuit board in the bonding region 320 and then connected to an integrated circuit.

For example, one of the first touch electrode 101 and the second touch electrode 102 is a transmitting electrode (Tx), while the other one of the first touch electrode 101 and the second touch electrode 102 is a receiving electrode (Rx). The embodiment illustrated in FIG. 3 is described by taking for example that the first touch electrode 101 is the transmitting electrode (Tx) while the second touch electrode 102 is the receiving electrode (Rx).

The touch structure provided by the embodiments of the present disclosure realizes the touch function by means of two touch layers, namely the first touch layer M1 and the second touch layer M2. The transmitting electrode (Tx) and the receiving electrode (Rx) are located at different layers, respectively. The first touch electrode 101 is formed integrally and the second touch electrode 102 is formed integrally. Neither the first touch electrode 101 nor the second touch electrode 102 needs to be formed through a via hole. Thus, the process risk is reduced.

For example, the first touch electrode 101 and the second touch electrode 102 form electrodes of a mutual capacitor. The transmitting electrode (Tx) may be input with a driving signal and the receiving electrode (Rx) may output an inductive signal. When a finger touches the touch structure, the capacitance at the touch position changes and the receiving electrode (Rx) outputs the inductive signal to obtain the touch position.

For example, as shown in FIG. 3 to FIG. 6, the plurality of first touch lines L1 are located at the first touch layer M1 and the plurality of second touch lines L2 are located at the second touch layer M2. That is, the first touch electrode 101 and the first touch line L1 connected to the first touch electrode 101 are located at the same layer, namely the first touch layer M1, and the second touch electrode 102 and the second touch line L2 connected to the second touch electrode 102 are located at the same layer, namely the second touch layer M2. The touch function may be realized by providing the two touch layers. The touch function includes detection of a touch position.

Because a distance between adjacent first touch lines L1 and a distance between adjacent second touch lines L2 are both small, FIG. 2 illustrates the plurality of first touch lines L1 using a region where the plurality of first touch lines L1 are located and the plurality of second touch lines L2 using a region where the plurality of second touch lines L2 are located.

FIG. 2 and FIG. 3 illustrate six touch line setting regions: region R1, region R2, region R3, region R4, region R5, and region R6. With reference to FIG. 2 and FIG. 3, two ends of the second touch electrode 102 on the left side as shown are connected to the second touch line L2 located in the region R1 and the second touch line L2 located in the region R3, respectively, and two ends of the second touch electrode 102 on the right side as shown are connected to the second touch line L2 located in the region R4 and the second touch line L2 located in the region R6, respectively. With reference to FIG. 2 and FIG. 3, two ends of the first touch electrode 101 are connected to the first touch line L1 located in the region R2 and the first touch line L1 located in the region R5, respectively.

As shown in FIG. 1 to FIG. 3, a base substrate BS includes an effective region 301 and a peripheral region 302 located on at least one side of the effective region 301. It is shown in the figures that the peripheral region 302 surrounds the effective region 301 for example. FIG. 1 and FIG. 2 further illustrate a bent region 310. As shown in FIG. 2, a portion located below the bent region 310 will be bent to a back side of a portion located above the bent region 310. As a matter of course, the bent region may also not be provided, i.e., the base substrate may also not be bent. FIG. 1 further illustrates a bonding region 320. Both of the bent region 310 and the bonding region 320 may be located in the peripheral region 302.

For example, as shown in FIG. 3, one of the first touch electrode 101 and the second touch electrode 102 extends in a first direction X, while the other one of the first touch electrode 101 and the second touch electrode 102 extends in a second direction Y, and the first direction X intersects the second direction Y. The embodiments of the present disclosure are illustrated by taking for example that the first touch electrode 101 extends in the first direction X and the second touch electrode 102 extends in the second direction Y.

For example, as shown in FIG. 3 and FIG. 6, the first touch electrode 101 is connected to at least one of the plurality of first touch lines L1. FIG. 3 and FIG. 6 are described by taking for example that the first touch electrode 101 is connected to two first touch lines L1. The first touch electrode 101 is connected to several first touch lines L1 to facilitate the transmission of a signal.

For example, as shown in FIG. 3 and FIG. 6, the first touch electrode 101 and the first touch lines L1 connected thereto are of an integrated structure. That is, the first touch electrode 101 is directly connected to the first touch lines L1.

For example, as shown in FIG. 3 and FIG. 7, the second touch electrode 102 is connected to at least one of the plurality of second touch lines L2. FIG. 3 and FIG. 7 are described by taking for example that the second touch electrode 102 is connected to two second touch lines L2. The second touch electrode 102 is connected to several second touch lines L2 to facilitate the transmission of a signal.

For example, as shown in FIG. 3 and FIG. 7, the second touch electrode 102 and the second touch lines L2 connected thereto are of an integrated structure. That is, the second touch electrode 102 is directly connected to the second touch lines L2.

For example, as shown in FIG. 4, at least one of the first insulating layer 11 and the second insulating layer 12 includes an optical clear adhesive (OCA).

For example, as shown in FIG. 4, the touch structure further includes a third insulating layer 13. The third insulating layer 13 is located on a side of the second touch layer M2 facing away from the second insulating layer 12. For example, the third insulating layer 13 includes optical clear adhesive (OCA).

For example, the OCA in the embodiments of the present disclosure may be an ordinary OCA. For example, the OCA may include a rubber OCA, an acrylic OCA, and an organosilicone OCA. The OCA has the characteristics of high light transmittance, low haze, ultraviolet resistance, high adhesion, high temperature resistance, and the like. For example, the OCA includes a double-sided adhesive tape of a non-backing material which is formed by making an optical acrylic adhesive into the non-backing material and sticking a release film to each of upper and lower sides.

In an embodiment of the present disclosure, at least one of the first insulating layer 11, the second insulating layer 12, and the third insulating layer 13 is an organic layer. Further for example, at least two of the first insulating layer 11, the second insulating layer 12, and the third insulating layer 13 are organic layers. An embodiment of the present disclosure is illustrated by taking for example that the first insulating layer 11, the second insulating layer 12, and the third insulating layer 13 are all organic layers.

FIG. 5A is another cross-sectional view of FIG. 3 taken along line A1-A2. As shown in FIG. 5A, the touch structure further includes a third touch line L3. The third touch line L3 is located at the first touch layer M1.

As shown in FIG. 5A, to reduce resistance and decrease power consumption, the first touch line L1 and the third touch line L3 are connected through a via hole V1 passing through the second insulating layer 12. As shown in FIG. 5A, a lead 111 includes the first touch line L1 and the third touch line L3 connected to each other. For example, each first touch electrode 101 is connected to at least one lead 111. The third touch line L3 and the second touch electrode 102 are insulated from each other.

As shown in FIG. 5B, the touch structure further includes a fourth touch line L4. The fourth touch line L4 is located at the second touch layer M2.

As shown in FIG. 5A, to reduce resistance and decrease power consumption, the fourth touch line L4 and the second touch line L2 are connected through a via hole V2 passing through the second insulating layer 12. As shown in FIG. 5A, a lead 112 includes the fourth touch line L4 and the second touch line L2 connected to each other. For example, each second touch electrode 102 is connected to at least one lead 112. The fourth touch line L4 and the first touch electrode 101 are insulated from each other.

For example, as shown in FIG. 3, FIG. 5A, and FIG. 5B, the via hole V1 and the via hole V2 are located in a periphery of the effective region 301 in which the plurality of first touch electrodes 101 and the plurality of second touch electrodes 102 are provided.

For example, as shown in FIG. 6, the first touch electrode 101 is of a mesh structure, and as shown in FIG. 7, the second touch electrode 102 is of the mesh structure. A partial structure in the effective region 301 of FIG. 2 is shown in an enlarging manner. As shown in FIG. 2, the effective region 301 includes a plurality of light emitting regions EMR. The mesh lines MS of the mesh structure are disposed around the light emitting region EMR.

For example, as shown in FIG. 3 and FIG. 6, to improve the etching uniformity, the optical uniformity, and the blanking property, the first touch layer M1 further includes a plurality of first dummy electrodes DMY1. The first dummy electrode DMY1 and the first touch electrode 101 are insulated from each other. For example, each first dummy electrode DMY1 is floated.

For example, as shown in FIG. 3 and FIG. 6, the first dummy electrode DMY1 is located between two adjacent first touch electrodes 101. For example, the plurality of first dummy electrodes DMY1 are uniformly distributed among the plurality of first touch electrodes 101.

For example, as shown in FIG. 3 and FIG. 6, the first dummy electrode DMY1 is of the mesh structure, and a mesh line of the first touch electrode 101 is disconnected from a mesh line of the first dummy electrode DMY1.

For example, to improve the etching uniformity, the optical uniformity, and the blanking property, the second touch layer M2 further includes a plurality of second dummy electrodes DMY2. The second dummy electrode DMY2 and the second touch electrode 102 are insulated from each other. For example, each second dummy electrode DMY2 is floated.

For example, as shown in FIG. 3 and FIG. 6, the second dummy electrode DMY2 is located between two adjacent second touch electrodes 102. For example, the plurality of second dummy electrodes DMY2 are uniformly distributed among the plurality of second touch electrodes 102.

For example, the second dummy electrode DMY2 is of the mesh structure, and a mesh line of the second touch electrode 102 is disconnected from a mesh line of the second dummy electrode DMY2.

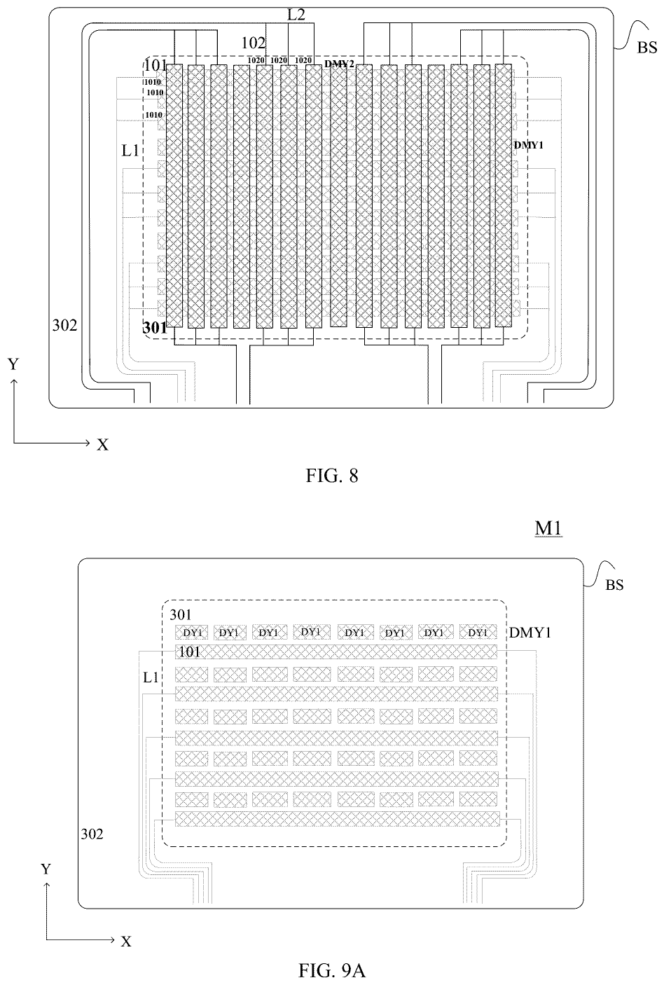

FIG. 8 is a plan view of a touch structure provided by another embodiment of the present disclosure. For example, as shown in FIG. 8, to increase a relative area of a mutual capacitor, a first touch electrode 101 includes a plurality of first touch portions 1010. The plurality of first touch portions 1010 are connected to each other. For example, as shown in FIG. 8, to increase the relative area of the mutual capacitor, a second touch electrode 102 includes a plurality of second touch portions 1020. The plurality of second touch portions 1020 are connected to each other.

As shown in FIG. 3, FIG. 6, and FIG. 8, a plurality of first touch electrodes 101 are arranged in a second direction Y, and each first touch electrode 101 extends in a first direction X.

As shown in FIG. 3, FIG. 7, and FIG. 8, a plurality of second touch electrodes 102 are arranged in the first direction X, and each second touch electrode 102 extends in the second direction Y.

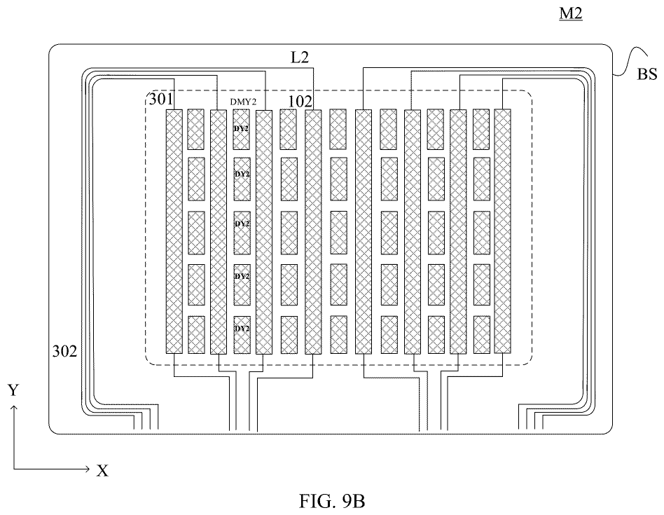

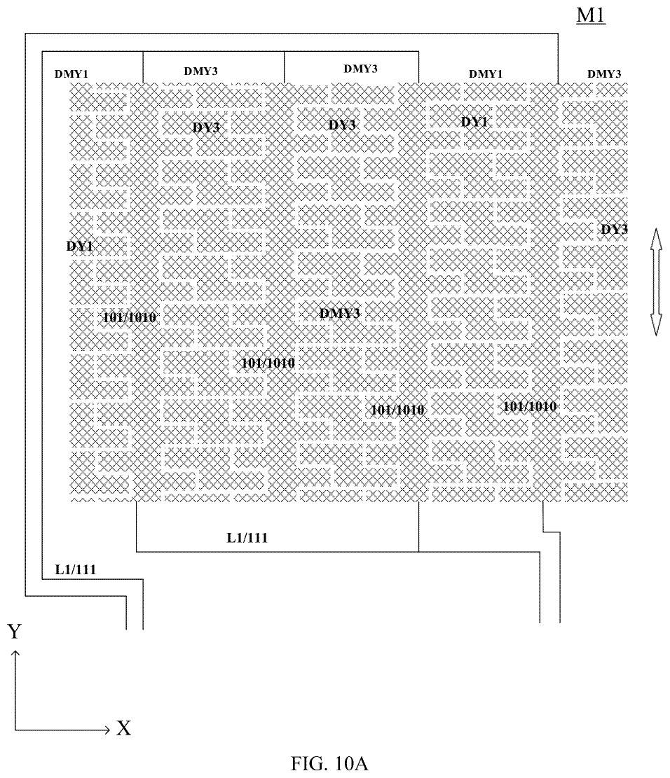

FIG. 9A is a plan view of a first touch layer in a touch structure provided by another embodiment of the present disclosure. FIG. 9B is a plan view of a second touch layer in a touch structure provided by another embodiment of the present disclosure.

As shown in FIG. 9A, a first dummy electrode DMY1 may include a plurality of first dummy sub-electrodes DY1, and two adjacent first dummy sub-electrodes DY1 are spaced apart from each other. Each first dummy sub-electrode DY1 is floated. As shown in FIG. 9A, the plurality of first dummy sub-electrodes DY1 are spaced apart from each other.

As shown in FIG. 9B, a second dummy electrode DMY2 may include a plurality of second dummy sub-electrodes DY2, and two adjacent second dummy sub-electrodes DY2 are spaced apart from each other. Each second dummy sub-electrode DY2 is floated. As shown in FIG. 9B, the plurality of second dummy sub-electrodes DY2 are spaced apart from each other.

With reference to FIG. 9A and FIG. 9B, the plurality of first dummy sub-electrodes DY1 in the same first dummy electrode DMY1 are arranged in a first direction X, and the plurality of second dummy sub-electrodes DY2 in the same second dummy electrode DMY2 are arranged in a second direction Y.

With reference to FIG. 9A and FIG. 9B, a size of the first dummy sub-electrode DY1 in the first direction X may be equivalent to a size of the second touch electrode 102 in the first direction X. For example, an orthographic projection of the second touch electrode 102 on the base substrate BS overlaps an orthographic projection of a plurality of first dummy sub-electrodes DY1 on the base substrate BS.

With reference to FIG. 9A and FIG. 9B, a size of the second dummy sub-electrode DY2 in the second direction Y may be equivalent to a size of the first touch electrode 101 in the second direction Y. For example, an orthographic projection of the first touch electrode 101 on the base substrate BS overlaps an orthographic projection of a plurality of second dummy sub-electrodes DY2 on the base substrate BS.

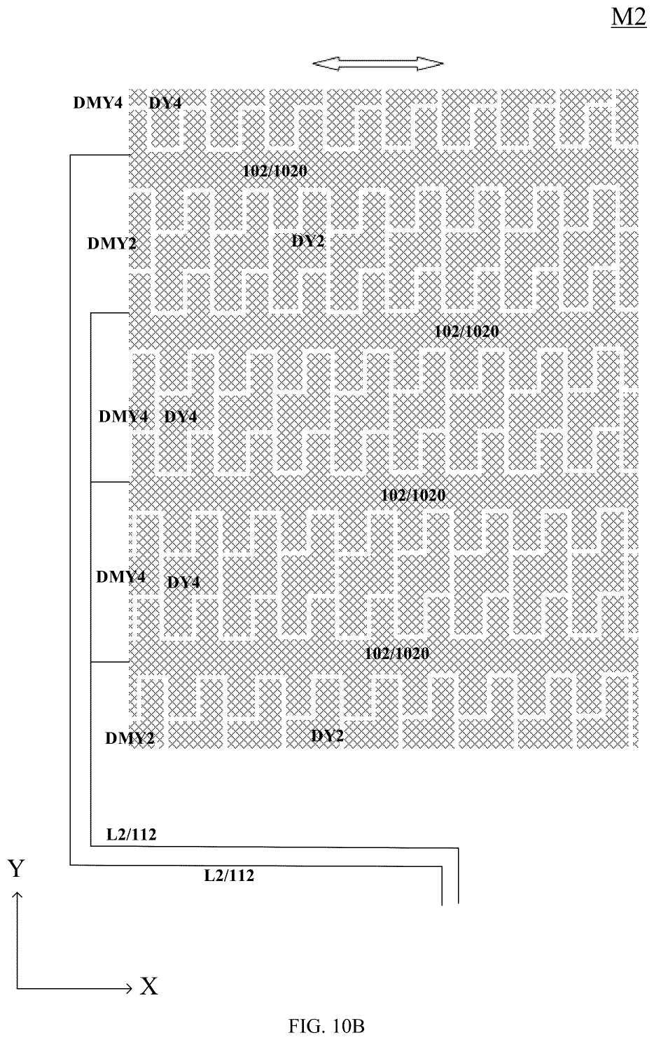

FIG. 10A is a partial plan view of a first touch layer in a touch structure provided by another embodiment of the present disclosure. FIG. 10B is a partial plan view of a second touch layer in a touch structure provided by another embodiment of the present disclosure.

FIG. 10A is a partial plan view of a first touch layer in the touch structure provided by another embodiment of the present disclosure, and FIG. 10B is a partial plan view of a second touch layer in the touch structure provided by another embodiment of the present disclosure.

As shown in FIG. 10A, the touch structure further includes a third dummy electrode DMY3. The third dummy electrode DMY3 is located between two adjacent first touch portions 1010 of the first touch electrode 101. The third dummy electrode DMY3 is of a mesh structure, and a mesh line of the first touch portion 1010 is disconnected from the mesh line of the third dummy electrode DMY3.

As shown in FIG. 10A, the third dummy electrode DMY3 includes a plurality of third dummy sub-electrodes DY3. A mesh line of one third dummy sub-electrode DY3 is disconnected from a mesh line of the third dummy sub-electrode DY3 adjacent thereto, and a mesh line of the third dummy sub-electrode DY3 is disconnected from a mesh line of the first touch portion 1010 adjacent thereto. For example, as shown in FIG. 10A, two adjacent third dummy sub-electrodes DY3 are separated from each other. For example, as shown in FIG. 10A, the plurality of third dummy sub-electrodes DY3 are spaced apart from each other.

As shown in FIG. 10B, the touch structure further includes a fourth dummy electrode DMY4. The fourth dummy electrode DMY4 is located between two adjacent second touch portions 1020 of the second touch electrode 102. The fourth dummy electrode DMY4 is of the mesh structure, and a mesh line of the second touch portion 1020 is disconnected from a mesh line of the third dummy electrode DMY3.

As shown in FIG. 10B, the fourth dummy electrode DMY4 includes a plurality of fourth dummy sub-electrodes DY4. A mesh line of one fourth dummy sub-electrode DY4 is disconnected from a mesh line of the fourth dummy sub-electrode DY4 adjacent thereto, and a mesh line of the fourth dummy sub-electrode DY4 is disconnected from a mesh line of the second touch portion 1020 adjacent thereto. For example, as shown in FIG. 10B, two adjacent fourth dummy sub-electrodes DY4 are separated from each other. As shown in FIG. 10B, the plurality of fourth dummy sub-electrodes DY4 are spaced apart from each other.

With reference to FIG. 10A and FIG. 10B, a size of the first dummy sub-electrode DY1 in the first direction X may be equivalent to a size of the second touch electrode 102 in the first direction X. For example, an orthographic projection of the second touch electrode 102 on the base substrate BS overlaps an orthographic projection of the plurality of first dummy sub-electrodes DY1 on the base substrate BS.

With reference to FIG. 10A and FIG. 10B, a size of the second dummy sub-electrode DY2 in the second direction Y may be equivalent to a size of the first touch electrode 101 in the second direction Y. For example, an orthographic projection of the first touch electrode 101 on the base substrate BS overlaps an orthographic projection of a plurality of second dummy sub-electrodes DY2 on the base substrate BS.

FIG. 10A further illustrates that the first dummy electrode DMY1 includes a plurality of first dummy sub-electrodes DY1 separated from each other. A shape and a size of the first dummy electrode DMY1 may be similar to, but not limited to, a shape and a size of the third dummy electrode DMY3, respectively. A shape and a size of the first dummy sub-electrode DY1 may be similar to, but not limited to, a shape and a size of the third dummy sub-electrode DY3, respectively.

FIG. 10B further illustrates that the second dummy electrode DMY2 includes a plurality of second dummy sub-electrodes DY2 separated from each other. A shape and a size of the second dummy electrode DMY2 may be similar to, but not limited to, a shape and a size of the fourth dummy electrode DMY4, respectively. A shape and a size of the second dummy sub-electrode DY2 may be similar to, but not limited to, a shape and a size of the fourth dummy sub-electrode DY4, respectively.

The black meshes in FIG. 10A and FIG. 10B represent the mesh lines of the touch electrodes of the mesh structure, and white lines between the black meshes represent positions where the mesh lines are disconnected. The double sided arrow in FIG. 10A represents an extension direction of the first touch line 101, and the first touch line 101 extends in the second direction Y. The double sided arrow in FIG. 10B represents second extension direction of the second touch line 102, and the second touch line 102 extends in the first direction X.

FIG. 10A and FIG. 10B are described by taking for example that the first dummy sub-electrode DY1, the second dummy sub-electrode DY2, the third dummy sub-electrode DY3, and the fourth dummy sub-electrode DY4 are all Z-shaped. However, without limitation thereto, other suitable shapes may also be used. The first dummy sub-electrode DY1, the second dummy sub-electrode DY2, the third dummy sub-electrode DY3, and the fourth dummy sub-electrode DY4 are all floated. In an embodiment of the present disclosure, the first dummy electrode DMY1, the second dummy electrode DMY2, the third dummy electrode DMY3, and the fourth dummy electrode DMY4 are all floated.

In an embodiment of the present disclosure, a component being floated refers to that no signal is input to the component.

In an embodiment of the present disclosure, an extension direction of a component represents an extension direction of an overall trend of the component.

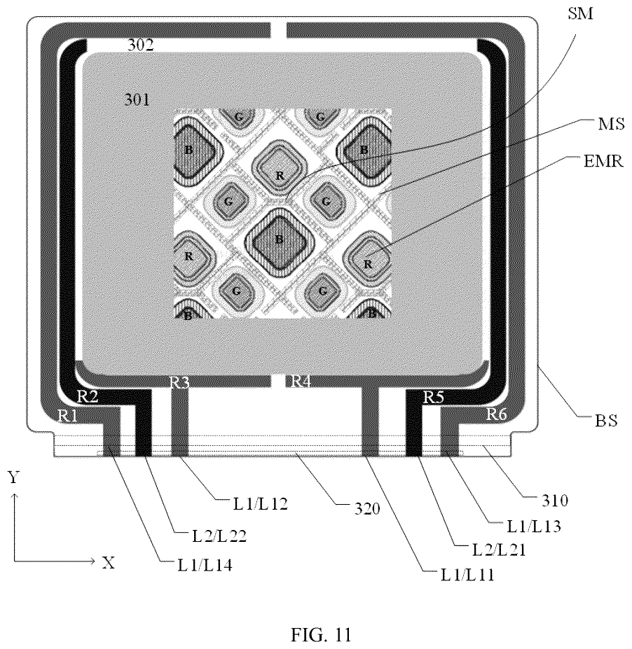

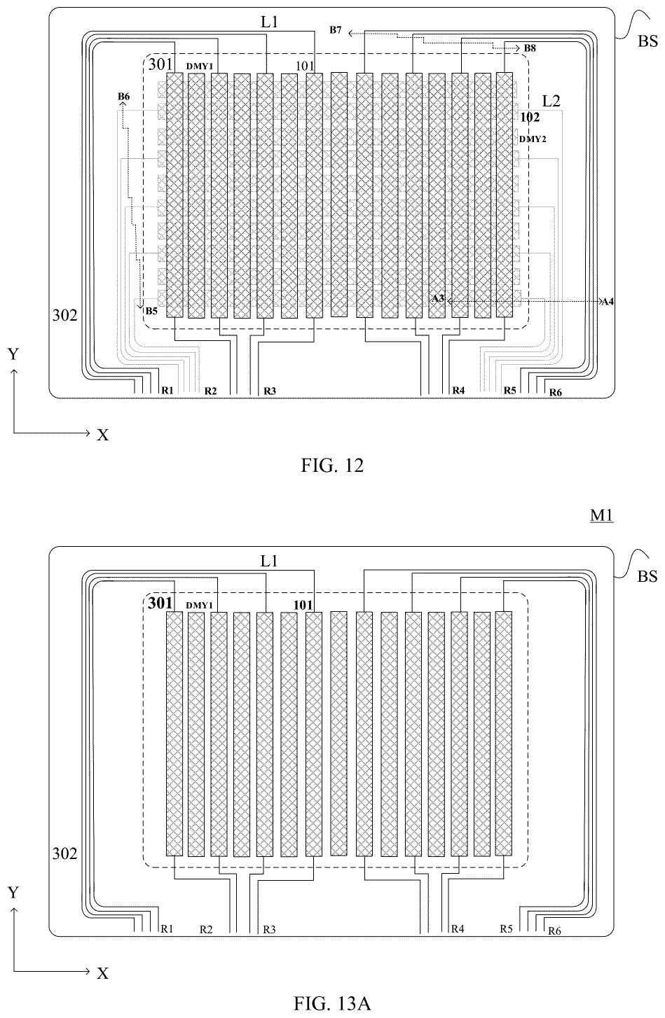

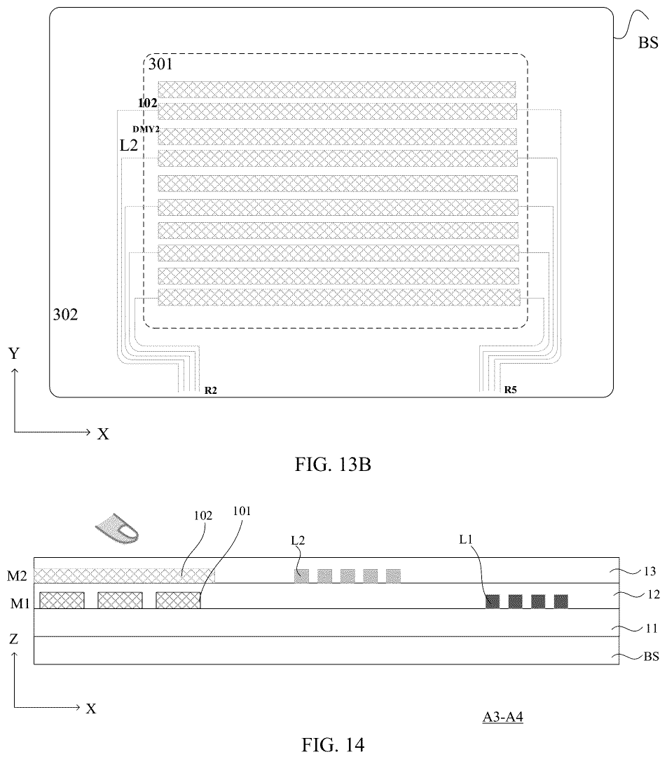

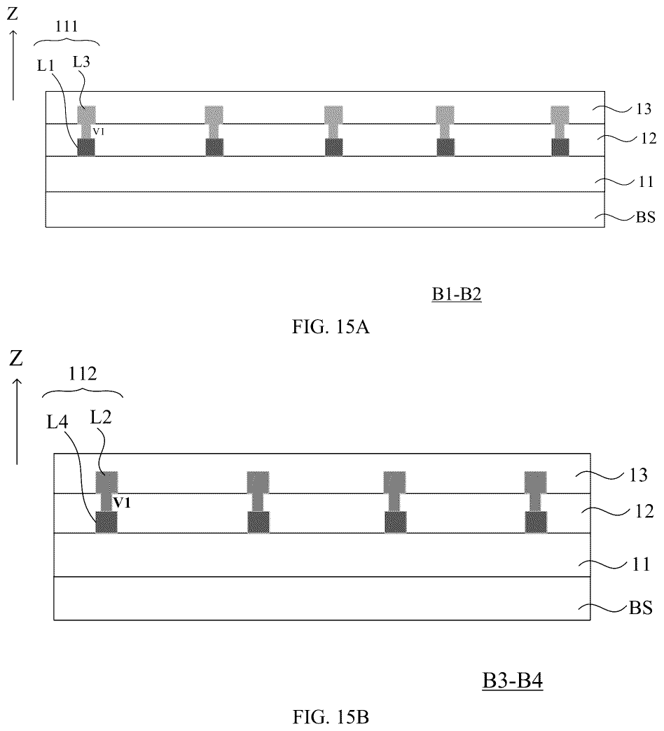

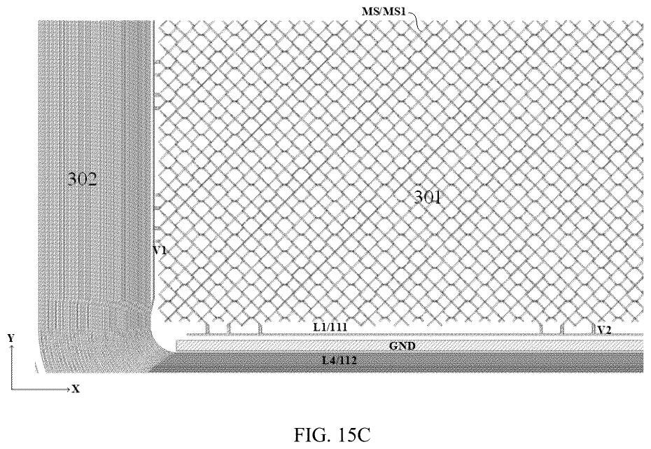

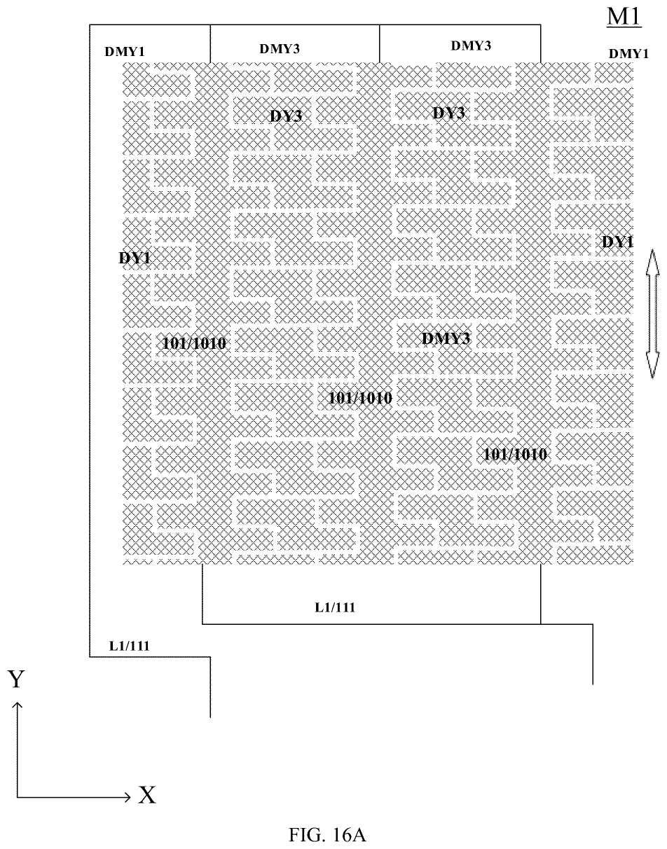

FIG. 11 is a plan view of a touch structure provided by another embodiment of the present disclosure. FIG. 12 is a plan view of a touch structure provided by an embodiment of the present disclosure. FIG. 13A is a plan view of a first touch layer in FIG. 12. FIG. 13B is a plan view of a second touch layer in FIG. 12. FIG. 14 is a cross-sectional view of FIG. 12 taken along line A3-A4. FIG. 15A is a cross-sectional view of FIG. 12 taken along line B5-B6. FIG. 15B is a cross-sectional view of FIG. 12 taken along line B7-B8. FIG. 15C is a plan view of a first touch layer and a second insulating layer in a touch structure provided by an embodiment of the present disclosure.

FIG. 11 and FIG. 12 illustrate six touch line setting regions: region R1, region R2, region R3, region R4, region R5, and region R6. With reference to FIG. 11 and FIG. 12, two ends of the first touch electrode 101 on the left side as shown are connected to the first touch line L1 located in the region R1 and the first touch line L1 located in the region R3, respectively, and two ends of the first touch electrode 101 on the right side as shown are connected to the first touch line L1 located in the region R4 and the first touch line L1 located in the region R6, respectively. With reference to FIG. 11 and FIG. 12, two ends of the second touch electrode 102 are connected to the second touch line L2 located in the region R2 and the second touch line L2 located in the region R5, respectively.

As shown in FIG. 15C, a via hole V1 and a via hole V2 are located in a periphery of an effective region. FIG. 15C further illustrates a ground line GND. The ground line GND is grounded. The ground line GND is located on a side of the first touch line L1 facing away from the effective region 301. At a position close to a bonding region 320 (as shown in FIG. 2), the ground line GND is located between the first touch line L1 and the fourth touch line L4. That is, the ground line GND is located between the lead 111 and the lead 112. The ground line GND plays a role in avoiding signal interference between the lead 111 connected to the first touch electrode and the lead 112 connected to the second touch electrode.

FIG. 15C further illustrates a mesh line MS1 of the first touch electrode 101, the effective region 301, and a peripheral region 302.

Compared with the touch structure shown in FIG. 3, in the touch structure shown in FIG. 12, the structures of the first touch layer M1 and the second touch layer M2 are reversed in position. That is, the structure of the second touch layer in FIG. 3 serves as the first touch layer in FIG. 12, and the structure of the first touch layer in FIG. 3 serves as the second touch layer in FIG. 12.

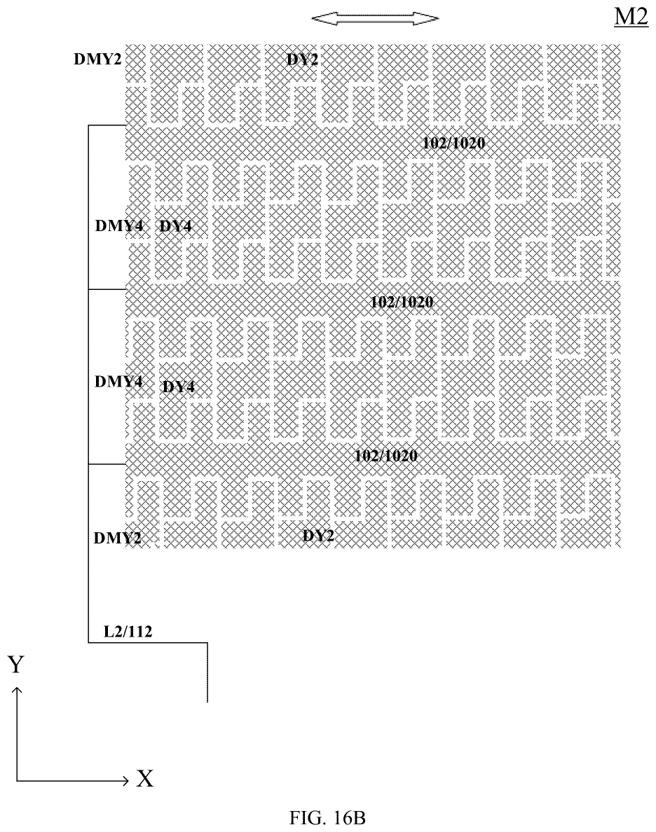

FIG. 16A is a partial plan view of a first touch layer in a touch structure provided by another embodiment of the present disclosure. FIG. 16B is a partial plan view of a second touch layer in a touch structure provided by another embodiment of the present disclosure.

FIG. 16A illustrates a first touch electrode 10, a first touch portion 1010, a first dummy electrode DMY1, a third dummy electrode DMY3, a first dummy sub-electrode DY1, a third dummy sub-electrode DY3, a lead 111, and a first touch line L1.

FIG. 16B illustrates a second touch electrode 20, a second touch portion 1020, a second dummy electrode DMY2, a fourth dummy electrode DMY4, a second dummy sub-electrode DY2, a fourth dummy sub-electrode DY4, a lead 112, and a second touch line L2.

FIG. 11 to FIG. 16B are described by taking for example that the second touch electrode 20 extending in a second direction Y is a receiving electrode (Rx) and the first touch electrode 10 extending in a first direction X is a transmitting electrode (Tx).

For example, a number of the first touch portions 1010 included in the first touch electrode 10 is equal to a number of the second touch portions 1020 included in the second touch electrode 20. In an embodiment of the present disclosure, the description is made by taking for example that the first touch electrode 10 includes three first touch portions 1010 and the second touch electrode 20 includes three second touch portions 1020.

In an embodiment of the present disclosure, the first dummy electrode DMY1, the second dummy electrode DMY2, the third dummy electrode DMY3, and the fourth dummy electrode DMY4 may have the same shape and the same size. However, without limitation thereto, different shapes and different sizes may also be used as required.

In an embodiment of the present disclosure, the first dummy sub-electrode DY1, the second dummy sub-electrode DY2, the third dummy sub-electrode DY3, and the fourth dummy sub-electrode DY4 may have the same shape and the same size. However, without limitation thereto, different shapes and different sizes may also be used as required.

It needs to be noted that, a film layer where the first touch electrode 10 is located, a film layer where the second touch electrode 20 is located, the extension direction of the first touch electrode 10, the extension direction of the second touch electrode 20 may be set as required and not limited to those shown in the figures.

For example, a component C being located on a side of a component B close to a component A and the component C being located on a side of the component B facing away from the component A refer to the component C being located on a lower side and an upper side of two opposite sides of the component B, respectively.

Some cross-sectional views of the embodiments of the present disclosure illustrate a third direction Z which is perpendicular to the first direction X and perpendicular to the second direction Y. For example, the first direction X intersects the second direction Y. Further for example, the first direction X is perpendicular to the second direction Y. For example, the first direction X and the second direction Y are directions parallel with a main surface of a base substrate, and the third direction Z is a direction perpendicular to the main surface of the base substrate. The main surface of the base substrate is a surface for fabricating components. An upper surface of the base substrate in the cross-sectional views is the main surface of the base substrate.

For example, for the touch structure, the effective region 301 may be regarded as a touch region, and for a touch display panel or a touch display apparatus, the effective region 301 may be regarded as a touch display region.

At least an embodiment of the present disclosure further provides a touch display panel including any touch structure described above. Because the touch display panel includes the touch structure described above, the touch display panel has the same technical effects with the touch structure, which will not be described redundantly here.

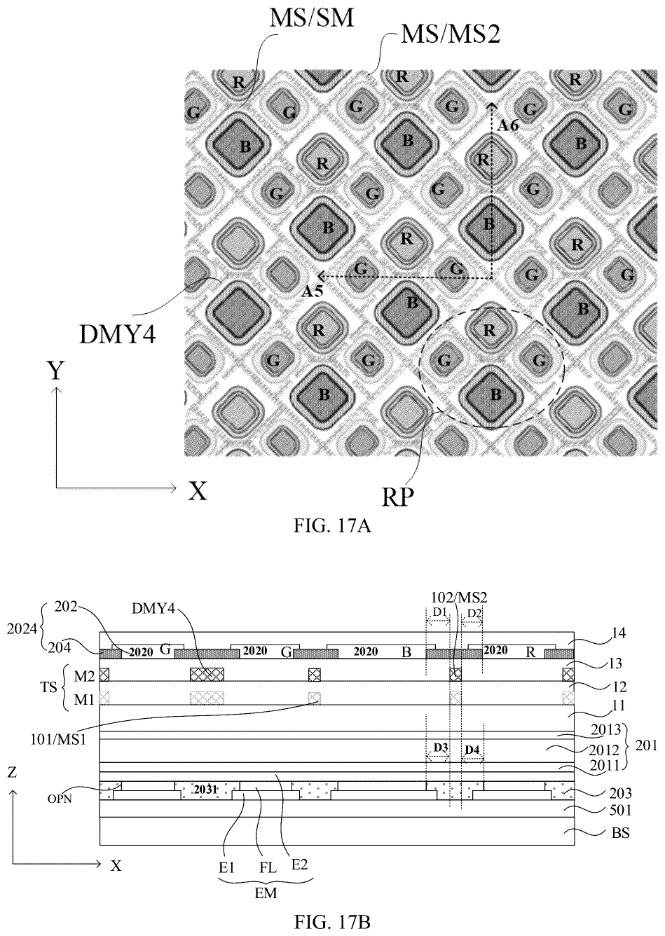

FIG. 17A is a plan view of a touch display panel provided by an embodiment of the present disclosure. FIG. 17B is a cross-sectional view of FIG. 17A taken along line A5-A6. With reference to FIG. 17A and FIG. 17B, the touch display panel further includes: a base substrate BS; a plurality of light emitting elements EM located on the base substrate BS; and an encapsulation layer 201 located on the plurality of light emitting elements EM; the encapsulation layer 201 is configured to encapsulate the plurality of light emitting elements EM, and the touch structure is located on a side of the encapsulation layer 201 facing away from the plurality of light emitting elements EM.

For example, the light emitting element EM includes an organic light emitting diode (OLED). FIG. 17B illustrates a first electrode E1, a second electrode E2, and a light emitting functional layer FL located between the first electrode E1 and the second electrode E2. Both of the first electrode E1 and the second electrode E2 are made of an electrically conductive material. For example, the material of one of the first electrode E1 and the second electrode E2 includes, but is not limited to, a metal, e.g., silver. For example, the material of the other one of the first electrode E1 and the second electrode E2 includes, but is not limited to, indium tin oxide (ITO).

For example, as shown in FIG. 17B, the encapsulation layer 201 includes a first encapsulation thin film 2011, a second encapsulation thin film 2012, and a third encapsulation thin film 2013. For example, both of the first encapsulation thin film 2011 and the third encapsulation thin film 2013 are inorganic thin films, and the second encapsulation thin film 2012 is an organic thin film. The encapsulation layer 201 may be fabricated using a usual material and by a usual method.

For example, as shown in FIG. 17B, the touch display panel further includes a pixel definition layer 203. The pixel definition layer 203 includes a plurality of openings OPN and a pixel definition portion 2031 located between two adjacent openings OPN. Orthographic projections of a plurality of first touch electrodes 101 and a plurality of second touch electrodes 102 on the base substrate BS overlap an orthographic projection of the pixel definition portion 2031 on the base substrate BS.

For example, as shown in FIG. 17B, to improve the light-exiting efficiency, an orthographic projection of at least a portion of mesh lines in the plurality of first touch electrodes 101 and the plurality of second touch electrodes 102 on the base substrate BS is located at a central position of the orthographic projection of the pixel definition portion 2031 on the base substrate BS.

For example, as shown in FIG. 17B, the touch display panel further includes a black matrix 204. The orthographic projections of a plurality of first touch electrodes 101 and a plurality of second touch electrodes 102 on the base substrate BS overlap an orthographic projection of the black matrix 204 on the base substrate BS.

For example, as shown in FIG. 17B, to avoid affecting the display effect caused by light reflected by the touch structure TS, the black matrix 204 is located on a side of the touch structure TS facing away from the base substrate BS. The orthographic projection of the black matrix 204 on the base substrate BS overlaps the orthographic projection of the first touch electrode 101 on the base substrate BS, and the orthographic projection of the black matrix 204 on the base substrate BS overlaps the orthographic projection of the second touch electrode 102 on the base substrate BS. That is, the first touch electrode 101 is disposed in a region in which the black matrix 204 is provided, and the second touch electrode 102 is disposed in a region in which the black matrix 204 is provided.

For example, as shown in FIG. 17B, the orthographic projection of the first touch electrode 101 on the base substrate BS overlaps the orthographic projection of the second touch electrode 102 on the base substrate BS.

For example, as shown in FIG. 17B, the touch display panel further includes a color filter layer 202. To improve the light-exiting efficiency, the color filter layer 202 includes a plurality of color filter units 2020. An orthographic projection of the plurality of color filter units 2020 on the base substrate BS does not overlap the orthographic projections of the plurality of first touch electrodes 101 and the plurality of second touch electrodes 102 on the base substrate BS.

For example, as shown in FIG. 17B, the color filter layer 202 is located on a side of the touch structure TS facing away from the base substrate BS.

As shown in FIG. 17B, the black matrix 204 and the color filter layer 202 form an anti-reflection layer 2024. The anti-reflection layer 2024 is located on a side of the touch structure TS facing away from the base substrate BS. FIG. 17B is described by taking for example that the anti-reflection layer 2024 includes the black matrix 204 and the color filter layer 202. In other embodiments, the anti-reflection layer 2024 may be a polarizer.

In the touch display panel provided by the embodiment of the present disclosure, by arranging the black matrix and the color filter layer on the encapsulation layer, it is unnecessary to arrange a polarizer, thereby improving the optical efficiency of the panel, reducing the power consumption, increasing a color rendering index, and optimizing the image quality. On the basis of an ordinary display screen, the transmissivity is improved by 33%. Less power is utilized to guarantee a brighter screen, and the power consumption of the organic light emitting diode (OLED) is reduced by 25%. Accordingly, a device including the touch display panel, such as a smart phone, may be enabled to have significantly increased use time and there is no need to worry about the power consumption. Meanwhile, vivid colors may be viewed by means of the screen. The color filter layer is added to present more realistic colors. The RGB sharpness may be improved by about 15%; and the color expression is improved.

For example, as shown in FIG. 17B, to improve the light-exiting efficiency, the orthographic projection of at least a portion of the mesh lines in the plurality of first touch electrodes 101 and the plurality of second touch electrodes 102 on the base substrate BS is located at the central position of the orthographic projection of the black matrix 204 on the base substrate BS.

For example, the central position of a component refers to a position where a center line of the component is located, without limitation thereto.

FIG. 17B illustrates the mesh line MS1 of the first touch electrode 101, the mesh line MS2 of the second touch electrode 102, and the fourth dummy electrode DMY4.

FIG. 17B further illustrates a control circuit layer 501. The control circuit layer 501 may include a plurality of pixel circuits, and each light emitting element may be connected to one pixel circuit. The pixel circuit provides a driving current to the light emitting element EM connected thereto to drive the light emitting element to emit light. For example, the pixel circuit may include structures such as a transistor and a storage capacitor.

FIG. 17B further illustrates a capping layer 14 to protect the structures on the base substrate.

With reference to FIG. 10A to FIG. 17B, the mesh lines MS of two adjacent first touch electrodes 101 are disconnected and the mesh lines MS of two adjacent second touch electrodes 102 are disconnected, and no via hole is formed in a region of the second insulating layer 12 that corresponds to the plurality of first touch electrodes 101 and the plurality of second touch electrodes 102 to reduce the process risk.

As shown in FIG. 17A, the plurality of sub-pixels include a red sub-pixel R, two green sub-pixels G, and a blue sub-pixel B, and the two green sub-pixels G are arranged in a first direction X, while the red sub-pixel R and the blue sub-pixel B are arranged in a second direction Y; the first direction X intersects the second direction Y; and the mesh lines MS included portions SM located among the red sub-pixels, the two green sub-pixels G, and the blue sub-pixel B and extending in the first direction X. This setting can be conducive to the setting of the mesh lines and conducive to improving the display effect.

As shown in FIG. 17A, a length of the portion SM of the mesh lines MS that extends in the first direction X is less than a maximum length of the light emitting region of the red sub-pixel R in the first direction X and less than a maximum length of the light emitting region of the blue sub-pixel B in the first direction X. This setting can be conducive to the setting of the mesh lines and conducive to improving the display effect.

As shown in FIG. 17A, one red sub-pixel R, two green sub-pixels G, and one blue sub-pixel B form a repetitive unit RP.

The structure of the display panel provided by the embodiment of the present disclosure is not limited to that shown in FIG. 17B. For example, some adjustments may be made on the basis of FIG. 17B.

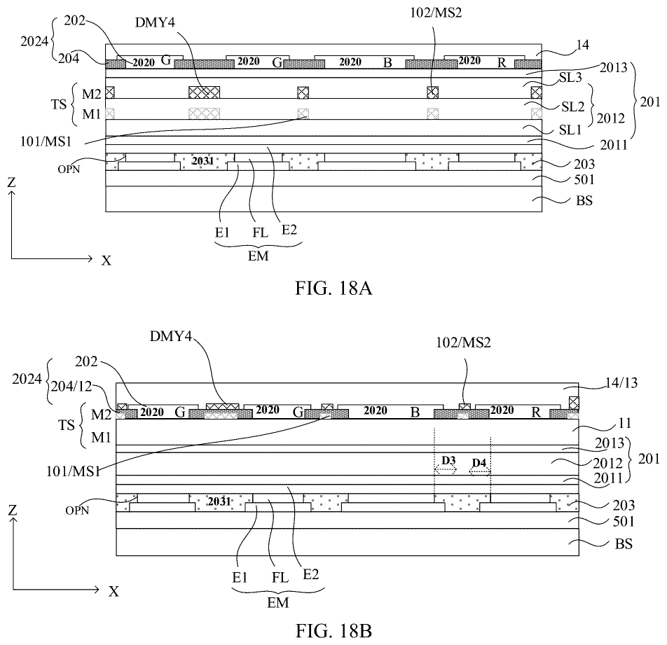

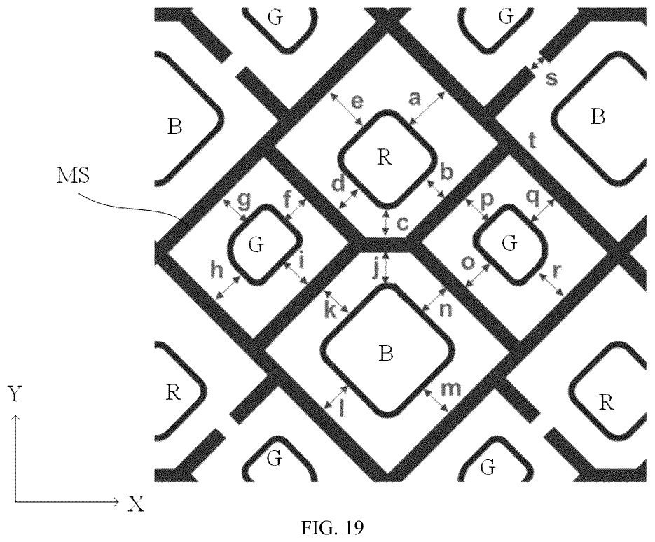

FIG. 18A is a cross-sectional view of a touch display panel provided by an embodiment of the present disclosure. FIG. 18B is a cross-sectional view of a touch display panel provided by an embodiment of the present disclosure.

For example, in some other embodiments, as shown in FIG. 18A, the touch structure TS may be located in an organic encapsulation thin film of an encapsulation layer, e.g., located in a second encapsulation thin film 2012. For example, in this case, the second encapsulation thin film 2012 may include three sub-layers stacked in sequence: a first sub-layer SL1, a second sub-layer SL2, and a third sub-layer SL3. The first sub-layer SL1 is closer to the base substrate than the third sub-layer SL3. A first touch layer M1 is formed on the first sub-layer SL1; the second sub-layer SL2 is formed on the first touch layer M1; a second touch layer M2 is formed on the second sub-layer SL2; and the third sub-layer SL3 is formed on the second touch layer M2. In this case, the first sub-layer SL1, the second sub-layer SL2, and the third sub-layer SL3 may be equivalent to a first insulating layer 11, a second insulating layer 12, and a third insulating layer 13, respectively.

For example, in some other embodiments, as shown in FIG. 18B, the position of the touch structure TS in FIG. 17B is adjusted to be in the proximity of an anti-reflection layer 2024. A black matrix BM of the anti-reflection layer 2024 may be used as one of the first insulating layer 11 and the second insulating layer 12 of the touch structure TS. FIG. 18B is described by taking for example that the black matrix BM is used as the second insulating layer 12 of the touch structure TS.

FIG. 19 is a plan view of mesh lines of light emitting regions and touch electrodes in a touch display panel provided by an embodiment of the present disclosure.

As shown in FIG. 17A to FIG. 19, the light emitting regions of a plurality of light emitting elements EM include the light emitting region of the green sub-pixel G, the light emitting region of the red sub-pixel R, and the light emitting region of the blue sub-pixel B.

FIG. 19 illustrates a spacing a to a spacing s and a line width/of the mesh line MS. The following table shows values in one embodiment. As a matter of course, the values in the following table are merely enumerative, and other suitable values may also be used for the spacing a to the spacing s and the line width t of the mesh line MS. For example, the line width t of the mesh line MS refers to a size of the mesh line MS in a direction perpendicular to the extension direction thereof.

TABLE 1
Spacing a to spacing s and line width t of mesh Line MS

| Spacing a to spacing s | |
|---|---|
| and line width t | Size(μm) |
| a | 14.5 |
| b | 8.3 |
| c | 8.7 |
| d | 9.3 |
| e | 14.3 |
| f | 8.7 |
| g | 9.7 |
| h | 11 |
| i | 9.5 |
| j | 9.3 |
| k | 10.7 |
| l | 10.4 |
| m | 10.5 |
| n | 9.8 |
| o | 10.3 |
| p | 9.6 |
| q | 9.8 |
| r | 11.1 |
| s | 6 |
| t | 3 |

For example, each of the spacing a to the spacing s and the line width t of the mesh line MS is less than 20 microns. Further for example, each of the spacing a to the spacing s and the line width t of the mesh line MS is less than 15 microns.

For example, as shown in FIG. 19 and the above table, spacings (the spacing a or the spacing e) between portions of a mesh line that are located between the green sub-pixels G and the red sub-pixels R in different repetitive units, and the light emitting regions of the green sub-pixels G or the red sub-pixels R therein are greater than a spacing (the spacing f, the spacing d, the spacing b, or the spacing p) between a portion of the mesh line that is located between the green sub-pixel G and the red sub-pixel R in the same repetitive unit, and the light emitting regions of the green sub-pixel G or the red sub-pixel R therein.

With reference to FIG. 17A to FIG. 19, distances of the orthographic projection of at least a portion of the mesh lines MS in the plurality of first touch electrodes 101 and the plurality of second touch electrodes 102 on the base substrate BS from orthographic projections of two opposite edges of the black matrix BM on the base substrate BS are equal or substantially equal.

FIG. 17B illustrates a distance D1 and a distance D2 of the orthographic projection of at least a portion of the mesh lines MS from the orthographic projections of the two opposite edges of the black matrix BM on the base substrate BS. For example, the distance D1 is equal to the distance D2 or there is only a little difference between the distance D1 and the distance D2.

With reference to FIG. 17A to FIG. 19, distances of the orthographic projection of at least a portion of the mesh lines MS in the plurality of first touch electrodes 101 and the plurality of second touch electrodes 102 on the base substrate BS from orthographic projections of two opposite edges of the pixel definition portion 2031 on the base substrate BS are equal or substantially equal.

FIG. 17B illustrates a distance D3 and a distance D4 of the orthographic projection of at least a portion of the mesh lines MS from the orthographic projections of the two opposite edges of the pixel definition portion 2031 on the base substrate BS. For example, the distance D3 is equal to the distance D4 or there is only a little difference between the distance D3 and the distance D4.

For example, the distances being substantially equal refer to that a ratio of a difference between the two distances to one of the two distances is less than or equal to 20%.

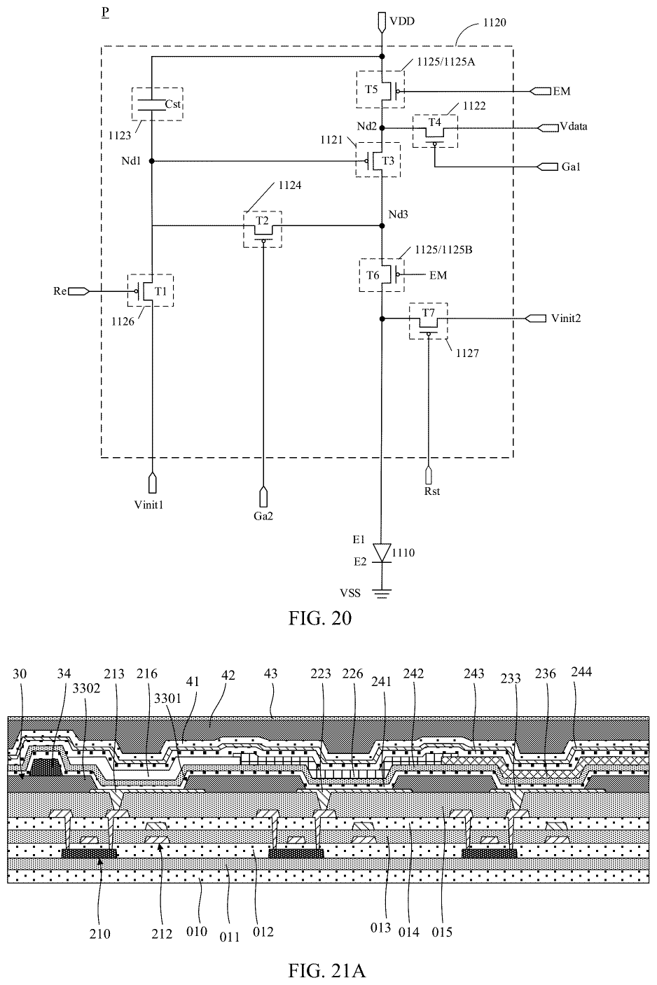

FIG. 20 is a schematic diagram of a pixel circuit and a light emitting element of a sub-pixel in a display panel provided by some embodiments of the present disclosure. For example, as shown in FIG. 20, the sub-pixel P includes a pixel circuit 1120 and a light emitting element 1110. The pixel circuit 1120 is configured to drive the light emitting element 1110.

FIG. 20 illustrates a circuit diagram of the pixel circuit of the display substrate provided by some embodiments of the present disclosure. The specific structure of the pixel circuit provided by some embodiments of the present disclosure is simply described below with reference to FIG. 20.

For example, a plurality of pixel circuits included in a plurality of sub-pixels P are disposed on the base substrate BS, and as shown in FIG. 1, in a display region R1 of the base substrate BS. For example, a gate driving circuit may be configured to output a plurality of output signals to the plurality of pixel circuits to control the plurality of pixel circuits to generate a plurality of driving currents for respectively driving the light emitting elements in the plurality of sub-pixels P to emit corresponding light, thereby realizing image display.

For example, as shown in FIG. 20, each sub-pixel P includes a pixel circuit 1120 and a light emitting element 1110.

For example, as shown in FIG. 20, the pixel circuit 1120 is configured to generate a driving current to control the light emitting element 1110 to emit light.

For example, the light emitting element 1110 includes a first electrode E1, a second electrode E2, and a light emitting functional layer disposed between the first electrode E1 and the second electrode E2. As shown in FIG. 20, the first electrode E1 of the light emitting element 1110 is electrically connected to the pixel circuit 1120, and the second electrode E2 of the light emitting element 1110 is electrically connected to a voltage terminal VSS. When the driving current generated by the pixel circuit 1120 flows through the light emitting element 1110, the light emitting functional layer of the light emitting element 1110 emits light of a brightness corresponding to a magnitude of the driving current.

For example, the light emitting element 1110 may be a light emitting diode or the like. The light emitting diode may be a micro light emitting diode (Micro LED), an organic light emitting diode (OLED), or a quantum dot light emitting diode (QLED), etc. The light emitting element 1110 is configured to receive a light emitting signal (e.g., which may be the driving current) when working and emit light of an intensity corresponding to the light emitting signal. The first electrode of the light emitting element 1110 may be a positive electrode, and the second electrode of the light emitting diode may be a negative electrode. It needs to be noted that in an embodiment of the present disclosure, the light emitting functional layer of the light emitting element 1110 may include an electroluminescent layer itself and common layers located on two sides of the electroluminescent layer. For example, the common layers may include a hole injection layer, a hole transport layer, an electron injection layer, an electron transport layer, etc. In practical application, the specific structure of the light emitting element 1110 may be designed and determined according to an actual application environment, which will not be defined here. For example, the light emitting element 1110 has a light emitting threshold voltage. The light emitting element 1110 emits light when a voltage between the first electrode and the second electrode of the light emitting element 1110 is greater than or equal to the light emitting threshold voltage.

For example, as shown in FIG. 20, the pixel circuit 1120 includes a driving sub-circuit 1121, a data writing sub-circuit 1122, a storage sub-circuit 1123, a compensation sub-circuit 1124, a light emitting control sub-circuit 1125, a first reset sub-circuit 1126, and a second reset sub-circuit 1127.

For example, the driving sub-circuit 1121 includes a first terminal, a second terminal, and a control terminal and is configured to generate the driving current for driving the light emitting element 1110 to emit light. For example, as shown in FIG. 20, the control terminal of the driving sub-circuit 1121 is electrically connected to a node Nd1, the first terminal of the driving sub-circuit 1121 is electrically connected to a node Nd2, and the second terminal of the driving sub-circuit 1121 is electrically connected to a node Nd3.

For example, as shown in FIG. 20, the data writing sub-circuit 1122 is electrically connected to the first terminal of the driving sub-circuit 1121 (i.e., the node Nd2) and a data signal line respectively, and configured to write a data signal Vdata provided by the data signal line to the first terminal of the driving sub-circuit 1121 in response to a scanning signal Ga1.

For example, as shown in FIG. 20, the storage sub-circuit 1123 is electrically connected to a voltage terminal VDD and the control terminal of the driving sub-circuit 1121 (i.e., the node Nd1) respectively, and configured to store a compensation signal obtained based on the data signal Vdata.

For example, as shown in FIG. 20, the compensation sub-circuit 1124 is electrically connected to the second terminal (i.e., the node Nd3) of the driving sub-circuit 1121 and the node Nd1 respectively, and configured for threshold compensation on the driving sub-circuit 1121 in response to a compensation control signal Ga2. The compensation signal stored in the storage sub-circuit 1123 represents a signal obtained after that threshold compensation has been performed.

For example, as shown in FIG. 20, the light emitting control sub-circuit 1125 is electrically connected to the first terminal and the second terminal of the driving sub-circuit 1121 respectively, and configured to control transfer of the driving current generated by the driving sub-circuit 1121 to the light emitting element 1110 in response to a light emitting control signal EM. For example, the light emitting control sub-circuit 1125 includes a first light emitting control sub-circuit 1125A and a second light emitting control sub-circuit 1125B. The first light emitting control sub-circuit 1125A is electrically connected to the first terminal of the driving sub-circuit 1121 (i.e., the node Nd2) and the voltage terminal VDD, and configured to realize connection or disconnection between the driving sub-circuit 1121 and the voltage terminal VDD in response to the light emitting control signal EM. The second light emitting control sub-circuit 1125B is electrically connected to the second terminal of the driving sub-circuit 1121 (i.e., the node Nd3) and the first electrode E1 of the light emitting element 1110 respectively, and configured to realize connection or disconnection between the driving sub-circuit 1121 and the light emitting element 1110 (e.g., the first electrode E1 of the light emitting element 1110) in response to the light emitting control signal EM.

For example, as shown in FIG. 20, the first reset sub-circuit 1126 is electrically connected to the node Nd1 (the control terminal of the driving sub-circuit 1121) and a first initialization voltage terminal Vinit1 respectively, and configured to reset the control terminal of the driving sub-circuit 1121 (i.e., the node Nd1) in response to a first reset control signal Re. For example, the first reset sub-circuit 1126 may write a first initialization voltage provided by the first initialization voltage terminal Vinit1 to the control terminal of the driving sub-circuit 1121 (i.e., the node Nd1) to reset the control terminal of the driving sub-circuit 1121.

For example, as shown in FIG. 20, the second reset sub-circuit 1127 is electrically connected to the first electrode of the light emitting element 1110 and a second initialization voltage terminal Vinit2 respectively, and configured to reset the first electrode E1 of the light emitting element 1110 in response to a second reset control signal Rst. For example, the second reset sub-circuit 1127 may write a second initialization voltage provided by the second initialization voltage terminal Vinit2 to the first electrode E1 of the light emitting element 1110 to reset the first electrode E1 of the light emitting element 1110.

For example, as shown in FIG. 20, the driving sub-circuit 1121 includes a driving transistor T3. The control terminal of the driving sub-circuit 1121 includes a gate electrode of the driving transistor T3, the first terminal of the driving sub-circuit 1121 includes a first electrode of the driving transistor T3, and the second terminal of the driving sub-circuit 1121 includes a second electrode of the driving transistor T3.

For example, as shown in FIG. 20, the data writing sub-circuit 1122 includes a data writing transistor T4. A gate electrode of the data writing transistor T4 is configured to receive the scanning signal Ga1, a first electrode of the data writing transistor T4 is electrically connected to the data signal line, and a second electrode of the data writing transistor T4 is electrically connected to the first electrode of the driving transistor T3, i.e., the second electrode of the data writing transistor T4 is electrically connected to the node Nd2.

For example, as shown in FIG. 20, the storage sub-circuit 1123 includes a storage capacitor Cst. A first terminal of the storage capacitor Cst is electrically connected to the gate electrode of the driving transistor T3. That is, the first terminal (a first electrode-plate) of the storage capacitor Cst is electrically connected to the node Nd1, and a second terminal (a second electrode-plate) of the storage capacitor Cst is electrically connected to the voltage terminal VDD.

For example, as shown in FIG. 20, the compensation sub-circuit 1124 includes a compensation transistor T2. A gate electrode of the compensation transistor T2 is configured to receive the compensation control signal Ga2, and a second electrode of the compensation transistor T2 is electrically connected to the second electrode of the driving transistor T3. That is, the second electrode of the compensation transistor T2 is electrically connected to the node Nd3, and the first electrode of the compensation transistor T2 is electrically connected to the node Nd1.

For example, as shown in FIG. 20, the first light emitting control sub-circuit 1125A includes a first light emitting control transistor T5, and the second light emitting control sub-circuit 1125B includes a second light emitting control transistor T6. For example, a gate electrode of the first light emitting control transistor T5 is configured to receive the light emitting control signal EM, a first electrode of the first light emitting control transistor T5 is connected to the voltage terminal VDD, and a second electrode of the first light emitting control transistor T5 is electrically connected to the first terminal of the driving sub-circuit 1221, i.e., the second electrode of the first light emitting control transistor T5 is electrically connected to the node Nd2. A gate electrode of the second light emitting control transistor T6 is configured to receive the light emitting control signal EM, a first electrode of the second light emitting control transistor T6 is electrically connected to the second terminal of the driving sub-circuit 1221, i.e., the first electrode of the second light emitting control transistor T6 is electrically connected to the node Nd3, and a second electrode of the second light emitting control transistor T6 is electrically connected to the first electrode E1 of the light emitting element 1110.

It needs to be noted that a signal for controlling the first light emitting control transistor T5 and a signal for controlling the second light emitting control transistor T6 may be different.

For example, as shown in FIG. 20, the first reset sub-circuit 1126 includes a first reset transistor T1, and the second reset sub-circuit 1127 includes a second reset transistor T7. A first electrode of the first reset transistor T1 is electrically connected to the first initialization voltage terminal Vinit1, a second electrode of the first reset transistor T1 is electrically connected to the node Nd1, and a gate electrode of the first reset transistor T1 is configured to receive the first reset control signal Re. A first electrode of the second reset transistor T7 is electrically connected to the second initialization voltage terminal Vinit2, a second electrode of the second reset transistor T7 is electrically connected to the first electrode E1 of the light emitting element 1110, and a gate electrode of the second reset transistor T7 is configured to receive the second reset control signal Rst.

For example, a value of the second initialization voltage of the second initialization voltage terminal Vinit2 is greater than a value of the first initialization voltage of the first initialization voltage terminal Vinit1. By increasing the second initialization voltage of the second initialization voltage terminal Vinit2, a current carrier within the light emitting element 1110 is rearranged, thereby reducing the defect of the current carrier, improving the stability of a device, and further improving the problem of screen flickering. However, the embodiments of the present disclosure are not limited thereto. The value of the second initialization voltage of the second initialization voltage terminal Vinit2 may also be equal to the value of the first initialization voltage of the first initialization voltage terminal Vinit1.

For example, the first reset transistor T1, the compensation transistor T2, the driving transistor T3, the data writing transistor T4, the first light emitting control transistor T5, the second light emitting control transistor T6, and the second reset transistor T7 are all polycrystalline silicon thin-film transistors, such as a low-temperature polycrystalline silicon (LTPS) thin-film transistors, and the embodiments of the present disclosure are not limited thereto. At least part of the first reset transistor T1, the compensation transistor T2, the driving transistor T3, the data writing transistor T4, the first light emitting control transistor T5, the second light emitting control transistor T6, and the second reset transistor T7 may also be oxide transistors.

For example, the first reset transistor T1, the compensation transistor T2, the driving transistor T3, the data writing transistor T4, the first light emitting control transistor T5, the second light emitting control transistor T6, and the second reset transistor T7 are all P-type transistors. However, the embodiments of the present disclosure are not limited thereto. At least part of the first reset transistor T1, the compensation transistor T2, the driving transistor T3, the data writing transistor T4, the first light emitting control transistor T5, the second light emitting control transistor T6, and the second reset transistor T7 may also be N-type transistors.

For example, one of a voltage output by the voltage terminal VDD and a voltage output by the voltage terminal VSS is a high voltage, and the other one is a low voltage. For example, in the embodiment as shown in FIG. 20, the voltage output by the voltage terminal VDD is a constant positive voltage, and the voltage output by the voltage terminal VSS is a constant negative voltage. For example, in some examples, the voltage terminal VSS may be grounded.

For example, in a specific implementation, in an embodiment of the present disclosure, the second initialization voltage Vi2 output by the second initialization voltage terminal Vinit2 and the voltage Vss output by the voltage terminal VSS may meet the following formula: Vi2−Vss<VEL, thus avoiding that the light emitting element 1110 emits light at a non-light emitting phrase. VEL represents the light emitting threshold voltage of the light emitting element 1110.

It needs to be noted that in addition to a 7T1C (7 transistors and 1 capacitor) pixel circuit, the pixel circuit may also be a circuit having other suitable structures, e.g., circuit structures such as 7T2C, 8T2C, 9T2C, 6T1C, and 6T2C, which will not be described redundantly here.

Before describing a pixel array and a display apparatus of embodiments of the present disclosure, concepts such as a sub-pixel, a first sub-pixel, a second sub-pixel, and a third sub-pixel mentioned in the following description are explained. In the embodiments of the present disclosure, the pixel array refers to an arrangement structure of light emitting devices of different colors in a display substrate, and an arrangement structure of the pixel circuits for driving the light emitting devices is not defined. Correspondingly, it will be appreciated that the sub-pixel in the embodiments of the present disclosure refers to a structure of light emitting device, and the first sub-pixel, the second sub-pixel, and the third sub-pixel represent three sub-pixels of different colors. The embodiments of the present disclosure are illustrated by taking for example that the first sub-pixel is the red sub-pixel, the second sub-pixel is the green sub-pixel, and the third sub-pixel is the blue sub-pixel. However, the first sub-pixel being the red sub-pixel, the second sub-pixel being the green sub-pixel, and the third sub-pixel being the blue sub-pixel do not constitute a limitation on the protection scope of the embodiments of the present disclosure. A first direction and a second direction involved in the embodiments of the present disclosure intersect. For example, one of the first direction and the second direction is a row direction, while the other one is a column direction. As a matter of course, the first direction and the second direction may also be any directions having a certain included angle. The embodiments of the present disclosure are illustrated by taking for example that the first direction is the row direction and the second direction is the column direction.

Usually, the shape of each sub-pixel is a pixel opening in the pixel definition layer and the light emitting layer is at least partially formed in the pixel opening, i.e., the shape of the sub-pixel mentioned in the embodiments of the present disclosure. The light emitting layer is formed by evaporation by using fine metal mask (FMM). That is, a shape of an FMM opening determines a shape of the light emitting layer. In other words, the shape and the size of the light emitting layer are consistent with the shape and the size of the FMM opening in the embodiments of the present disclosure. Therefore, in the description of the following embodiment of the present disclosure, the shape of the pixel opening represents the shape of the sub-pixel, and the shape of the light emitting region represents the shape of the FMM opening. When the pixel opening is a quadrangular, the sub-pixel is quadrangular.

Any sub-pixel has a display center (hereinafter referred to as center for short), and the center refers to a planar geometric center of the pixel opening of the sub-pixel. In an embodiment of the present disclosure, each sub-pixel has a virtual center. In a case where the shape of the sub-pixel is a regular shape, for example, the shape of the sub-pixel is a regular polygon, a circle, or an ellipse, the virtual center of the sub-pixel is the geometric center of the sub-pixel. That is, the center of the sub-pixel coincides with the virtual center. In a case where the shape of the sub-pixel is not a regular shape, for example, the shape of the sub-pixel has at least one vertex angle different from other vertex angles in shape as compared with a rectangle, the center of the sub-pixel does not coincide with the virtual center thereof. The virtual center of such a sub-pixel may be determined in the following way: an extension direction of a width and an extension direction of a length of the sub-pixel are taken as a width extension direction and a length extension direction of a defining quadrangle, respectively, and the width and the length of the sub-pixel are taken as a width and a length of the defining quadrangle, respectively, and an intersection point of diagonals of the defining quadrangle is taken as a virtual pixel center of the sub-pixel. The length direction of the sub-pixel, e.g., the length direction of a polygon, may pass through the geometric center thereof, and the longest size parallel with or perpendicular to one edge is, for example, a long edge length for a similar rectangle, is a length of a connecting line passing through the center and perpendicular to a set of parallel edges for a similar hexagon, and is a length of a connecting line perpendicular to one edge and connecting opposite angles thereof for a similar pentagon. For a circle or an ellipse, the length direction thereof is a direction of a diameter or a major axis, and so on. The width direction of the sub-pixel is a direction perpendicular to the length direction.

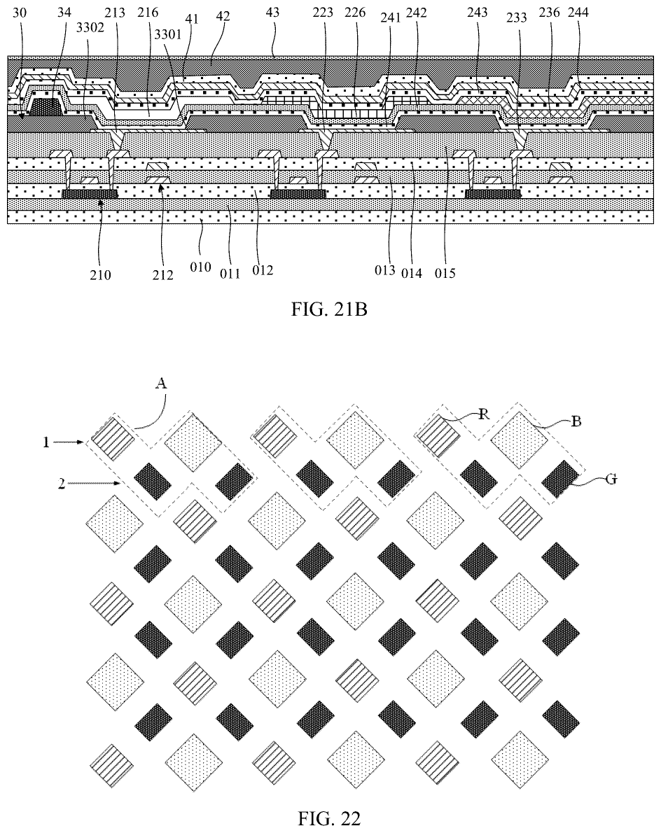

In addition, an embodiment of the present disclosure is illustrated by taking for example that the shape of at least one of the red sub-pixel, the green sub-pixel, and the blue sub-pixel includes a polygon, and an embodiment of the present disclosure is illustrated by taking for example that the red sub-pixel, the green sub-pixel, and the blue sub-pixel are all polygons and the polygon is a quadrangle. The polygon may have more than three angles according to the shape thereof. Regarding a pair of vertex angles, for example, the polygon includes N vertex angles and the vertex angles are ranked in sequence with the same vertex angle as a start point; the 1^{st} and (N/2+1)^{th} vertex angles are opposite angles, the 2^{nd} and (N/2+1)^{th} vertex angles are opposite angles, . . . , and the (N/2−1)^{th} and N^{th} vertex angles are opposite angles. For example, the quadrangle or the similar quadrangle includes four vertex angles. Each polygon includes four vertex angles: a first angle, a second angle, a third angle, and a fourth angle, for example, the first angle and the third angle are disposed oppositely and the second angle and the fourth angle are disposed oppositely. As a matter of course, it will be appreciated that if the sub-pixel is polygonal, the number of the vertex angles thereof may also be more, which will not be limited in the embodiments of the present disclosure. However, it needs to be noted that the so-called vertex angle in the present embodiment is not necessarily an included angle between two lines, and actually it is also possible that portions of two lines of a certain vertex angle that extend towards the vertex thereof and intersect form an arc segment or a straight-line segment such that the vertex angle becomes a circular chamfer or a flat chamfer. To make the structure of each sub-pixel in a pixel array in an embodiment of the present disclosure clear, a film layer structure of the pixel array in the embodiments of the present disclosure is described below in combination with a preparation method of the pixel array. FIG. 21A is a schematic structural diagram of a film layer structure of an exemplary pixel array. As shown in FIG. 1, the method may specifically include the following steps.
(1) A base substrate is prepared on a glass carrier plate.

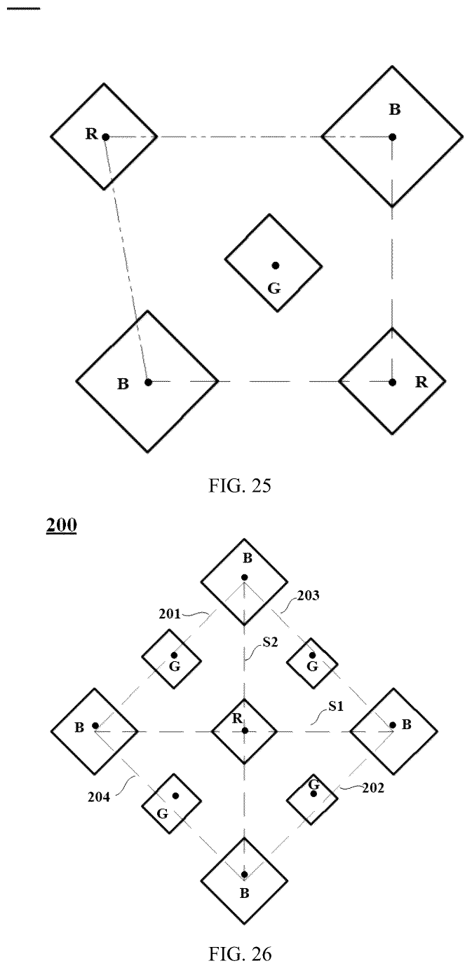

In some exemplary implementations, the base substrate 10 may be a flexible base substrate, and includes, for example, a first flexible material layer, a first inorganic material layer, a semiconductor layer, a second flexible material layer, and a second inorganic material layer that are stacked on the glass carrier plate. The material of the first flexible material layer and the second flexible material layer is a material such as polyimide (PI), polyethylene terephthalate (PET), or a surface treated polymer soft film. The material of the first inorganic material layer and the second inorganic material layer is a silicon nitride (SiNx) or a silicon oxide (SiOx) and used to improve the water and oxygen resisting capability of the base substrate. The first inorganic material layer and the second inorganic material layer are also referred to as barrier layers. The material of the semiconductor layer is amorphous silicon (a-Si). In some exemplary implementations, taking a stacked structure PI1/Barrier1/a-Si/PI2/Barrier2 for example, the preparation process thereof includes: firstly applying the polyimide to the glass carrier plate 1 to form a first flexible (PI1) layer after curing; subsequently, depositing a barrier thin film on the first flexible layer to form a first barrier (Barrier1) layer covering the first flexible layer; then depositing an amorphous silicon thin film on the first barrier layer to form an amorphous silicon (a-Si) layer covering the first barrier layer; then applying the polyimide to the amorphous silicon to form a second flexible (PI2) layer after curing; and then depositing a barrier thin film on the second flexible layer to form a second barrier (Barrier2) layer covering the second flexible layer, thereby completing the preparation of the base substrate 10, as shown in FIG. 26.
(2) A driving structure layer is prepared on the base substrate. The driving structure layer includes a plurality of driving circuits. Each driving circuit includes a plurality of transistors and at least one storage capacitor. For example, a 2T1C, 3T1C, or 7T1C design is adopted. Three sub-pixels are taken for example, and the driving circuit of each sub-pixel includes only one transistor and one storage capacitor for example.

In some embodiments, the preparation process of the driving structure layer may be as described below. The following description is made by taking the preparation process of the driving circuit of the red sub-pixel for example.

A first insulating thin film and an active layer thin film are orderly deposited on the base substrate 10. The active layer thin film is patterned through a patterning process to form a first insulating layer 011 covering the whole base substrate 010 and an active layer pattern disposed on the first insulating layer 011. The active layer pattern includes at least a first active layer.

Subsequently, a second insulating thin film and a first metal thin film are orderly deposited. The first metal thin film is patterned through a patterning process to form a second insulating layer 012 covering the active layer pattern and a first gate metal layer pattern disposed on the second insulating layer 012. The first gate metal layer pattern includes at least a first gate electrode and a first capacitor electrode.

Subsequently, a third insulating thin film and a second metal thin film are orderly deposited. The second metal thin film is patterned through a patterning process to form a third insulating layer 013 covering the first gate metal layer and a second gate metal layer patter disposed on the third insulating layer 013. The second gate metal layer pattern includes at least a second capacitor electrode, and the position of the second capacitor electrode corresponds to the position of the first capacitor electrode.

Subsequently, a fourth insulating thin film is deposited. The fourth insulating thin film is patterned through a patterning process to form a pattern of a fourth insulating layer 014 covering the second gate metal layer. At least two first via holes are formed in the fourth insulating layer 014, and parts of the fourth insulating layer 014, the third insulating layer 013, and the second insulating layer 012 within two first via holes are etched off to expose a surface of the first active layer.

Subsequently, a third metal thin film is deposited. The third metal thin film is patterned through a patterning process to form a source-drain metal layer pattern on the fourth insulating layer 014. A source-drain metal layer includes at least a first source electrode and a first drain electrode that are located in a display region. The first source electrode and the first drain electrode may be connected to the first active layer through the first via holes, respectively.

In the driving circuit of the red sub-pixel in the display region, the first active layer, the first gate electrode, the first source electrode, and the first drain electrode may form a first transistor 210, and the first capacitor electrode and the second capacitor electrode may form a first storage capacitor 212. In the above preparation process, the driving circuit of the green sub-pixel and the driving circuit of the blue sub-pixel may be formed simultaneously.

In some exemplary implementations, the first insulating layer 011, the second insulating layer 012, the third insulating layer 013, and the fourth insulating layer 014 are made of any one or more of a silicon oxide (SiOx), a silicon nitride (SiNx), and silicon oxynitride (SiON), and may each be a single layer, a plurality of layers, or a composite layer. The first insulating layer 011 is referred to as a buffer layer for improving the water and oxygen resisting capability of the base substrate. The second insulating layer 012 and the third insulating layer 013 are referred to as gate insulator (GI) layer. The fourth insulating layer 014 is referred to as an interlayer dielectric (ILD) layer. The first metal thin film, the second metal thin film, and the third metal thin film are made of a metal material, such as one or more of silver (Ag), copper (Cu), aluminum (Al), titanium (Ti), and molybdenum (Mo), or an alloy material of the above metals, such as an aluminum-neodymium alloy (AlNd) or a molybdenum-niobium alloy (MoNb), and may each be of a single-layer structure or a multi-layer composite structure, such as Ti/Al/Ti. The active layer thin film is made of one or more materials of an amorphous indium gallium zinc oxide material (a-IGZO), zinc oxynitride (ZnON), indium zinc tin oxide (IZTO), amorphous silicon (a-Si), polycrystalline silicon (p-Si), sexithiophene, polythiophene, and the like. That is, the present disclosure is applicable to transistors manufactured based on the oxide technology, the silicon technology, and the organic matter technology.
(3) A planarization layer is formed on the base substrate on which the aforesaid patterns are formed.

In some exemplary implementations, the base substrate 010 on which the aforesaid patterns are formed is coated with a planarization thin film of an organic material to form a planarization (PLN) layer 015 covering the whole base substrate 010, and a plurality of second via holes are formed in the planarization layer 015 of the display region. Part of the planarization layer 015 within the plurality of second via holes is etched off to expose a surface of the first drain electrode of the first transistor 210 of the driving circuit of the red sub-pixel, a surface of the first drain electrode of the first transistor of the driving circuit of the green sub-pixel, and a surface of the first drain electrode of the first transistor of the driving circuit of the blue sub-pixel 03, respectively.
(4) A pattern of first electrode is formed on the base substrate on which the aforesaid patterns are formed. In some examples, the first electrode is a reflecting positive electrode.

In some exemplary implementations, a conductive thin film is deposited on the base substrate 010 on which the aforesaid patterns are formed. The conductive thin film is patterned through a patterning process to form a pattern of the first electrode. A first positive electrode 213 of the red sub-pixel is connected to the first drain electrode of the first transistor 210 through the second via hole, a second positive electrode 223 of the green sub-pixel 2 is connected to the first drain electrode of the first transistor of the green sub-pixel through the second via hole, and a third positive electrode 233 of the blue sub-pixel 23 is connected to the first drain electrode of the first transistor of the blue sub-pixel through the second via hole.

In some examples, the first electrode may be made of a metal material, such as one or more of magnesium (Mg), silver (Ag), copper (Cu), aluminum (Al), titanium (Ti), and molybdenum (Mo), or an alloy material of the above metals, such as an aluminum-neodymium alloy (AlNd) or a molybdenum-niobium alloy (MoNb), and may each be of a single-layer structure or a multi-layer composite structure, such as Ti/Al/Ti, or a stack structure formed of a metal and a transparent electrically conductive material, e.g., a reflective material such as ITO/Ag/ITO and Mo/AlNd/ITO.
(5) A pattern of pixel definition layer (PDL) is formed on the base substrate on which the aforesaid patterns are formed.

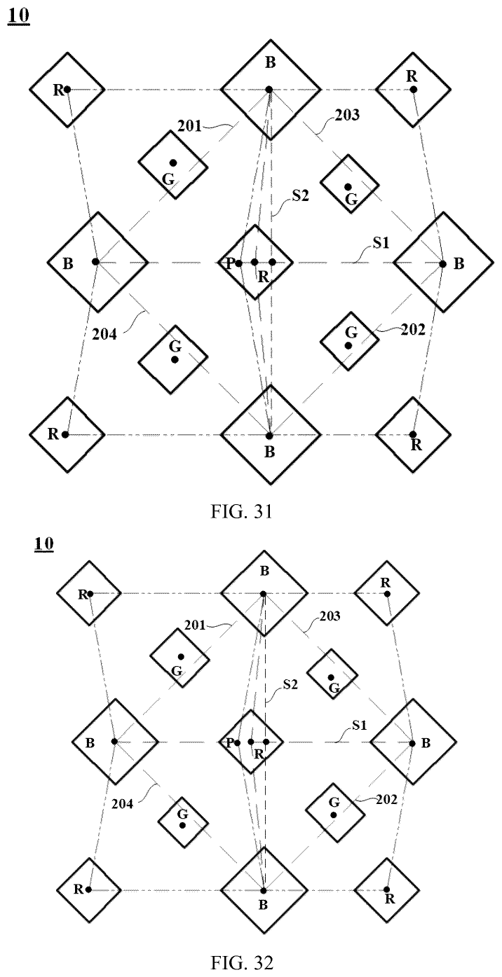

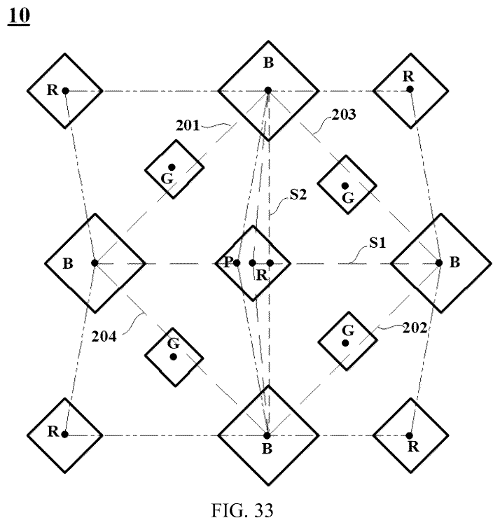

In some exemplary implementations, the base substrate 010 on which the aforesaid patterns are formed is coated with a pixel definition thin film, and a pattern of the pixel definition layer is formed through masking, exposure, and development processes. As shown in FIG. 32, the pixel definition layer 30 of the display region includes a plurality of pixel definition portions 3302. A plurality of pixel openings 3301 are formed between adjacent pixel definition portions 3302. Part of the pixel definition layer 30 within the plurality of pixel openings 3301 is etched off to expose at least part of surface of the first positive electrode 213 of the red sub-pixel, at least part of surface of the second positive electrode 223 of the green sub-pixel, and at least part of surface of the third positive electrode 233 of the blue sub-pixel, respectively.

In some examples, the pixel definition layer 30 may be made of polyimide, acrylic, polyethylene terephthalate, or the like.
(6) A pattern of post spacer (PS) is formed on the base substrate on which the aforesaid patterns are formed.

In some exemplary implementations, the base substrate 010 on which the aforesaid patterns are formed is coated with an organic material thin film, and a pattern of the post spacer 34 is formed through masking, exposure, and development processes. The post spacer 34 may serve as a support layer configured to support an FMM in an evaporation process. In some examples, two adjacent post spacers 34 are spaced by a repetitive unit in the row arrangement direction of sub-pixels. For example, the post spacer 34 may be located between red sub-pixel and blue sub-pixel 03 that are adjacent to each other.
(7) An organic functional layer and a second electrode are orderly formed on the base substrate on which the aforesaid patterns are formed. In some examples, the second electrode is a transparent negative electrode. The light emitting element may emit light through the transparent negative electrode from the side facing away from the base substrate 010, thereby realizing top-emitting. In some examples, the organic functional layer of the light emitting element includes a hole injection layer, a hole transport layer, a light emitting layer, and an electron transport layer.

In some exemplary implementations, a hole injection layer 241 and a hole transport layer 242 are orderly formed by evaporation on the base substrate 010 on which the aforesaid patterns are formed using an open mask, and then a blue light emitting layer 236, a green light emitting layer 216, and a red light emitting layer 226 are orderly formed by evaporation using an FMM, and then an electron transport layer 243, a negative electrode 244, and an optical coupling layer 245 are orderly formed by evaporation using the open mask. The hole injection layer 241, the hole transport layer 242, the electron transport layer 243, and the negative electrode 244 are each a common layer for a plurality of sub-pixels. In some examples, the organic functional layer may further include a microcavity adjustment layer located between the hole transport layer and the light emitting layer. For example, a blue microcavity adjustment layer, a blue light emitting layer, a green microcavity adjustment layer, a green light emitting layer, a red microcavity adjustment layer, and a red light emitting layer may be orderly formed by evaporation using an FMM after the hole transport layer is formed.

In some exemplary implementations, as shown in FIG. 21A, due to the limitation of an FMM opening, the blue light emitting layer 236, green light emitting layer 216, and red light emitting layer 226 that are adjacent and are formed by evaporation may overlap. FIG. 21B is a schematic diagram of a film layer structure of another exemplary pixel array. As can be seen from FIG. 21B, the blue light emitting layer 236, green light emitting layer 216, and red light emitting layer 226 that are adjacent may also not overlap. In other words, the light emitting layers formed with FMMs having different opening sizes are also different in size. In some exemplary implementations, the organic functional layer is formed within a sub-pixel region to realize connection of the organic functional layer with the positive electrode. The negative electrode is formed on the pixel definition layer and connected to the organic functional layer.

In some exemplary implementations, the negative electrode may be made of any one or more of magnesium (Mg), silver (Ag), and aluminum (Al), or an alloy made of any one or more of the above metals, or a transparent electrically conductive material, e.g., indium tin oxide (ITO), or may be of a multi-layer composite structure of a metal and a transparent electrically conductive material.

In some exemplary implementations, an optical coupling layer may be formed on a side of the negative electrode 244 facing away from the base substrate 10, and the optical coupling layer may be a common layer for a plurality of sub-pixels. The optical coupling layer may coordinate with the transparent negative electrode to achieve the effect of increasing light output. For example, the material of the optical coupling layer may be a semiconductor material. However, the present embodiment is not limited to this.
(8) An encapsulation layer is formed on the base substrate on which the aforesaid patterns are formed.

In some exemplary implementations, the encapsulation layer is formed on the base substrate 010 on which the aforesaid patterns are formed. The encapsulation layer may include a first encapsulation layer 41, a second encapsulation layer 42, and a third encapsulation layer 43 that are stacked. The first encapsulation layer 41 may be made of an inorganic material to cover the negative electrode 244 in the display region. The second encapsulation layer 42 is made of an organic material. The third encapsulation layer 43 is made of an inorganic material to cover the first encapsulation layer 41 and the second encapsulation layer 42. However, the present embodiment is not limited to this. In some examples, the encapsulation layer may be of an inorganic/organic/inorganic/organic/inorganic five-layer structure. The first encapsulation layer 41, the second encapsulation layer 42, and the third encapsulation layer 43 may be referred to as a first encapsulation thin film, a second encapsulation thin film, and a third encapsulation thin film, respectively.

FIG. 22 illustrates a schematic diagram of an exemplary pixel array. As shown in FIG. 22, the pixel array includes a plurality of rows of first pixel groups 1 and a plurality of rows of second pixel groups 2, and the first pixel groups 1 and the second pixel groups 2 are disposed alternately. The first pixel group 1 is formed by red sub-pixel R and blue sub-pixels B that are disposed alternately, and the red sub-pixel R and the blue sub-pixels B in the same column of the plurality of rows of first pixel groups 1 are also disposed alternately. The second pixel group 2 is formed by a plurality of green sub-pixels G disposed side by side, and the green sub-pixel G is staggered with the red sub-pixel R and the blue sub-pixel B in an adjacent row. For this pixel arrangement, the pixel array may be divided into repetitive units arranged in an array. Each repetitive unit includes two rows and four columns of sub-pixels. That is, each repetitive unit includes 1 red sub-pixel R, 1 blue sub-pixel B, and 2 green sub-pixels G. The red sub-pixel R and the blue sub-pixel B are common sub-pixels. By a virtual algorithm, 4 sub-pixels may be enabled to realize the display of 2 virtual pixel units. For example, the red sub-pixel R in the second repetitive unit of the first row, the blue sub-pixel B in the first repetitive unit of the first row and the green sub-pixel G closest thereto form a virtual pixel unit, and the red sub-pixel R in the second repetitive unit of the first row, the blue sub-pixel B in the repetitive unit and the green sub-pixel G closest thereto form a virtual pixel unit. In addition, the blue sub-pixel B in the second repetitive unit of the first row, another green sub-pixel G in the repetitive unit and the red sub-pixel R closest thereto in the third repetitive unit of the first row form a virtual pixel unit. Thus, the resolution of a display panel employing the pixel array can be effectively improved.

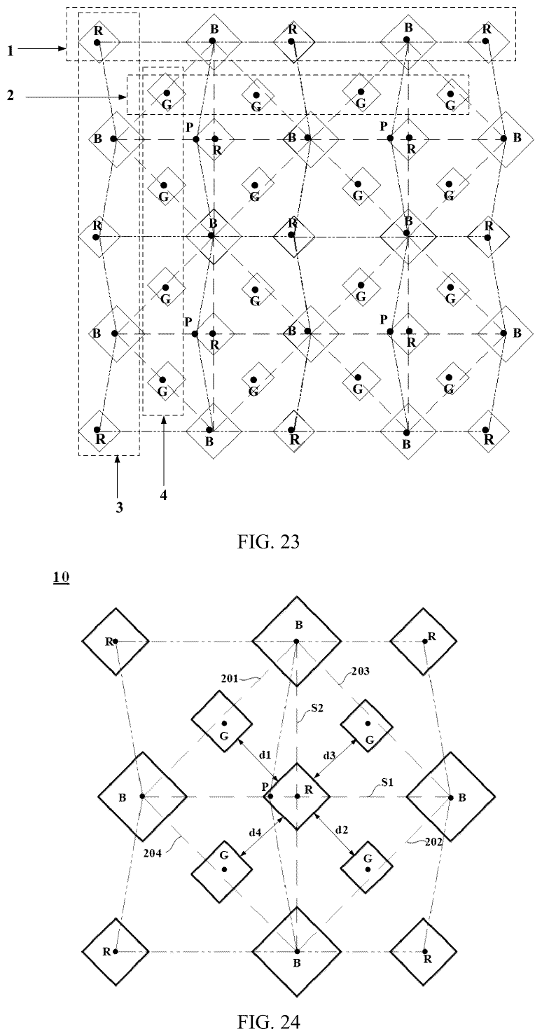

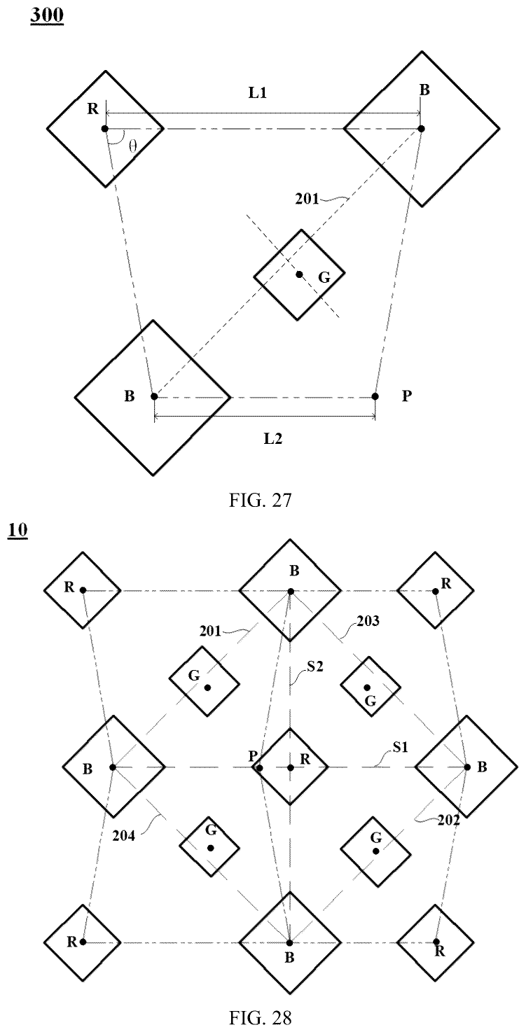

In an aspect, FIG. 23 is a schematic diagram of a pixel array according to an embodiment of the present disclosure. FIG. 24 is a schematic diagram of an arrangement of sub-pixels in a first virtual polygon according to an embodiment of the present disclosure. FIG. 25 is a schematic diagram of an arrangement of sub-pixels in a second virtual quadrangle in the first virtual polygon of FIG. 24. FIG. 26 is schematic diagram of an arrangement of sub-pixels in a third virtual quadrangle in the first virtual polygon of FIG. 24. FIG. 27 is a schematic diagram of an arrangement of sub-pixels in a virtual isosceles trapezoid 300 in the first virtual polygon of FIG. 24. As shown in FIG. 23 to FIG. 27, an embodiment of the present disclosure provides a pixel array that includes a plurality of sub-pixels, and the plurality of sub-pixels include a red sub-pixel R, a green sub-pixel G, and a blue sub-pixel B.

Referring continuously to FIG. 23, the red sub-pixels R and the blue sub-pixels B in the pixel array are disposed alternately in a row direction to form the first pixel group 1; the green sub-pixels G are disposed at intervals in the row direction to form the second pixel group 2; the red sub-pixels R and the blue sub-pixels B are disposed alternately in a column direction to form a third pixel group 3; and the green sub-pixels G are disposed at intervals in the column direction to form a fourth pixel group 4. The first pixel groups 1 and the second pixel groups 2 are arranged alternately in the column direction, and the third pixel groups 3 and the fourth pixel groups 4 are arranged alternately in the row direction. In an embodiment of the present disclosure, sequential connecting lines of virtual centers of two red sub-pixels R and two blue sub-pixels B between two adjacent first pixel groups 1 and two adjacent third pixel groups 2 form a second virtual quadrangle 100; and any two adjacent second virtual quadrangles 100 share an adjacent edge. The adjacent edge may be, for example, a connecting line of the virtual centers of the adjacent red sub-pixel R and blue sub-pixel B in one first pixel group 1, or a connecting line of the virtual centers of the adjacent red sub-pixel R and blue sub-pixel B in one third pixel group 3. One green sub-pixel G is disposed in each second virtual quadrangle 100. Four second virtual quadrangles 100 arranged in an array form a first virtual polygon 10 in such a manner that adjacent edges are shared. For example, with reference to FIG. 25, one first virtual polygon 10 in the embodiment of the present disclosure includes 13 sub-pixels, and 8 sub-pixels are located at edges of the first virtual polygon 10, which are 4 red sub-pixels R and 4 blue sub-pixels B, respectively; and 5 sub-pixels are located within the first virtual polygon, which are 1 red sub-pixel R and 4 green sub-pixels G. In addition, as can be seen from FIG. 25, the first virtual polygon 10 may be a hexagon and is a concave hexagon having three sets of parallel edges, with a set of longest parallel edges being parallel with the row direction or the column direction. Four virtual isosceles trapezoids 300 are symmetrical relative to the straight line of the longest edge of the hexagon, e.g., symmetrical up and down.

In an embodiment of the present disclosure, there is a first virtual point P within the first virtual polygon 10, and connecting lines of the first virtual point P with four blue sub-pixels B divide the first virtual polygon 10 into four virtual isosceles trapezoids 300.

It needs to be noted here that the virtual isosceles trapezoid 300 in the embodiment of the present disclosure is not an isosceles trapezoid in the strict sense, and any trapezoid of which a difference between two base angles is less than 10° is regarded as the so-called isosceles trapezoid in the embodiment of the present disclosure.

In an embodiment of the present disclosure, by designing an arrangement manner of the red sub-pixels R, the green sub-pixels G, and the blue sub-pixels B, the display effect of the display apparatus in the embodiment of the present disclosure can be effectively improved; the display sharpness is improved; and the edge jaggedness and the granular sensation of display are reduced.

In some embodiments, both of areas of the red sub-pixel R and the blue sub-pixel B are greater than an area of the green sub-pixel G so that the service life of a display apparatus can be improved.

In some embodiments, a third virtual quadrangle 200 formed by connecting the virtual centers of four blue sub-pixels B in one first virtual polygon 10 includes, but is not limited to a square, and may also be, for example, a rhombus or a parallelogram. An embodiment of the present disclosure is described with reference to the case where the third virtual quadrangle 200 is the square as an example. A first edge 201 and a second edge 202 of the third virtual quadrangle 200 are disposed oppositely, and a third edge 203 and a fourth edge 204 are disposed oppositely, and two diagonals of the third virtual quadrangle 200 are denoted by S1 and S2, respectively.

It needs to be noted here that in an embodiment of the present disclosure, four edges of the third virtual quadrangle 200 are connected end to end to form the quadrangle in the following counterclockwise order: the first edge 201, the third edge 203, the second edge 202, and the fourth edge 204, or connected end to end in the following clockwise order: the first edge 201, the fourth edge 204, the second edge 202, and the third edge 203.

In some examples, the green sub-pixels G in the pixel array have two sizes, the green sub-pixels G in an odd-numbered column (an odd number of fourth pixel groups 4) have the same size, and the green sub-pixels G in an even-numbered column (an even number of fourth pixel groups 4) have the same size. Alternatively, the green sub-pixels G in the odd-numbered rows in the same column (of the fourth pixel groups) have the same size, and the green sub-pixels G in the even-numbered rows have the same size.

In some examples, the green sub-pixels G of two sizes in the pixel array have the sizes of 0.5 to 2. Further, the green sub-pixels G of the two sizes have the sizes of 0.7 to 1.5.

In some examples, the sizes of four green sub-pixels G in the same first virtual polygon 10 are equal. As a matter of course, in an embodiment of the present disclosure, it is also possible that the sizes of all the green sub-pixels G in the pixel array are equal, and this case facilities the preparation of the green sub-pixels G.

In some embodiments, as shown in FIG. 24, the virtual center of the red sub-pixel R within the first virtual polygon 10 may be located at the center of the third virtual quadrangle 200, i.e., located at the position of the intersection point of S1 and S2. In some embodiments, the virtual center of the red sub-pixel R within the first virtual polygon 10 may be not located at the center of the third virtual quadrangle, e.g., located at any position in S1 and S2 other than the center points of S1 and S2.

In some embodiments, in the case where the connecting line of the virtual centers of the red sub-pixel R and the blue sub-pixel B in the first pixel group 1 is roughly in the same straight line, both of the virtual center of the red sub-pixel R and the first virtual point P within the first virtual polygon 10 are located in S1. As a matter of course, in the case where the connecting line of the virtual centers of the red sub-pixel R and the blue sub-pixel B in the third pixel group 3 is roughly in the same straight line, both of the virtual center of the red sub-pixel R and the first virtual point P within the first virtual polygon 10 are located in S2.

In some embodiments, a distance of the vertex of the first angle of at least one of the red sub-pixel R, the green sub-pixel G, and the blue sub-pixel B from the virtual center is unequal to a distance of the opposite angle to the first angle from the virtual center. For example, the distance of the vertex of the first angle of at least one of the red sub-pixel R, the green sub-pixel G, and the blue sub-pixel B from the virtual center is less than the distance of the opposite angle to the first angle from the virtual center. The first angles of the red sub-pixel R, the green sub-pixel G, and the blue sub-pixel B are all circular chamfers or flat chamfers.

In some embodiments, distances of the red sub-pixel R in the first pixel group 1 from two blue sub-pixels B adjacent thereto are unequal, thus increasing the aperture ratio of the pixels.

In some examples, to guarantee that the sub-pixels are more compact, the aperture ratio can be effectively increased. A distance between the light emitting region and the pixel opening of each sub-pixel is set to be about 5-20 μm, and further be about 8-18 μm. In some examples, a distance between the pixel openings of two sub-pixels emitting light of the same color is about 5-20 μm, and further about 8-18 μm. For example, a spacing between two red sub-pixels R in the same row is about 10-20 μm. Correspondingly, in some examples, a distance between the light emitting regions of two sub-pixels emitting light of the same color is about 5-20 μm, further about 8-18 μm, and further about 1-5 μm. The distance between the light emitting regions of the sub-pixels, the distance between the pixel openings, and the distance between the light emitting region and the pixel opening may be further set according to the requirements of a panel size, a resolution, and an aperture ratio. In some embodiments, as shown in FIG. 27, the top edge and the bottom edge of the virtual isosceles trapezoid 300 are L1 and L2, respectively, and a vertex angle of the virtual isosceles trapezoid 300 is θ, 45°<θ<135°; L1=Pitch+Pitch*cot θ; L2=Pitch−Pitch*cot θ, i.e., L1/L2−Pitch+Pitch*cot θ/Pitch−Pitch*cot θ, where Pitch is a pixel pitch. The pixel pitch is a half of the distance between the virtual centers of adjacent red sub-pixels R in the same first pixel group 1 (or third pixel group 3), or a half of the distance between the virtual centers of adjacent blue sub-pixels B in the same first pixel group 1 (or third pixel group 3), or a distance between the virtual centers of adjacent green sub-pixels G in the same second pixel group 2 (or fourth pixel group 4). The pixel pitch is, for example, a half of the distance between the virtual centers of pixel openings between two adjacent red sub-pixels R in the row direction. In some examples, the pixel pitch is, for example, roughly sizes of the pixel driving circuits of 2 sub-pixels in the row direction. In some examples, the pitch is roughly a size of the pixel driving circuit of 1 sub-pixel in the column direction. In some examples, the pixel pitch is roughly equal to a size of the display region in the row direction divided by a number of pixels in the row direction, or a size of the display region in the column direction divided by a number of pixels in the column direction. For example, for a quarter high definition (QHD) product, the resolution is 960×540, and the pixel pitch is roughly equal to the size of the display region in the row direction divided by 960, or the size of the display region in the column direction divided by 540. For a high definition (HD) product, the pixel pitch is roughly equal to the size of the display region in the row direction divided by 1280, or the size of the display region in the column direction divided by 720. For a full high definition (FHD) product, the pixel pitch is roughly equal to the size of the display region in the row direction divided by 1920, or the size of the display region in the column direction divided by 1080. For a quad high definition (QHD) product, the pixel pitch is roughly equal to the size of the display region in the row direction divided by 2560, or the size of the display region in the column direction divided by 1440. For an ultra high definition (UHD) product, the pixel pitch is roughly equal to the size of the display region in the row direction divided by 3840, or the size of the display region in the column direction divided by 2160.

The sub-pixels in the first virtual polygon 10 are described below in combination with specific examples.

In one example, as shown in FIG. 24, the red sub-pixel R, the green sub-pixel G, and the blue sub-pixel B are all quadrangular (e.g., square or rectangular). In this case, the virtual centers of the red sub-pixel R, the green sub-pixel G, and the blue sub-pixel B are respective centers (intersection points of diagonals). Sequential connecting lines of the centers of two red sub-pixels R and two blue sub-pixels B arranged in an array form a second virtual quadrangle 100; and any two adjacent second virtual quadrangles 100 share an edge. One green sub-pixel G is disposed in each second virtual quadrangle 100. Four second virtual quadrangles 100 arranged in an array form a first virtual polygon 10. As shown in FIG. 24, the centers of the red sub-pixel R and the blue sub-pixel B located on the first virtual polygon 10 and in the same row are roughly in the same straight line, and in this case, the first virtual polygon 10 is a hexagon. There is a first virtual point P within the first virtual polygon 10, and the first virtual point P is located in S1, and together with the connecting lines of the first virtual point with four blue sub-pixels B divide the first virtual polygon 10 into four virtual isosceles trapezoids 300.

Referring continuously to FIG. 26, the sequential connecting lines of the centers of four blue sub-pixels B on the first virtual polygon 10 form a third virtual quadrangle 200. The third virtual quadrangle 200 includes, but is not limited to a square. In an embodiment of the present disclosure, the case where the third virtual quadrangle 200 is the square is taken as an example. The two diagonals of the third virtual quadrangle 200 are S1 and S2, respectively, and the first virtual point P is located in S1. The red sub-pixel R within the first virtual polygon 10 is located at the center of the third virtual quadrangle 200, i.e., located at the position of the intersection point of S1 and S2. Referring continuously to FIG. 26, one green sub-pixel G is disposed within one virtual isosceles trapezoid 300, and the green sub-pixels G located in the same column (the second pixel group 2) have the same size, while the green sub-pixels G located in the same row (the fourth pixel group 4) have different sizes. However, distances of the four green sub-pixels G from the red sub-pixel R within the first virtual polygon 10 are equal, i.e., d1=d2=d3=d4. As a matter of course, the distances of the four green sub-pixels G from the red sub-pixel R within the first virtual polygon 10 may also be unequal. The center of a blue sub-pixel B within each virtual isosceles trapezoid 300 is located in a midperpendicular to the connecting line of the centers of two blue sub-pixels B located on the virtual isosceles trapezoid 300. In other words, the center of the green sub-pixel G located at the top left corner within the virtual isosceles trapezoid 300 is located in a midperpendicular to the first edge 201; the center of the green sub-pixel G located at the bottom right corner within the virtual isosceles trapezoid 300 is located in a midperpendicular to the second edge 202; the center of the green sub-pixel G located at the top right corner within the virtual isosceles trapezoid 300 is located in a midperpendicular to the third edge 203; and the center of the green sub-pixel G located at the bottom left corner within the virtual isosceles trapezoid 300 is located in a midperpendicular to the fourth edge 204. Further, four green sub-pixels G within the first virtual polygon 10 are disposed mirror-symmetrically with S1 as an axis of symmetry.

In some embodiments, distances of the centers of the green sub-pixels G within any virtual isosceles trapezoid 300 from the connecting line of the centers of two blue sub-pixels B are roughly equal. As a matter of course, depending on a different size of the pixel array, the distances of the centers of the green sub-pixels G from the connecting line of the centers of two blue sub-pixels B may also be unequal. It needs to be noted that “roughly equal” in the embodiments of the present disclosure means “equal”, or a distance between two items being within a preset range.

In another example, FIG. 28 is a schematic diagram of another first virtual polygon 10 according to an embodiment of the present disclosure. As shown in FIG. 28, the first virtual polygon 10 has a roughly same pixel distribution with the first virtual polygon 10 shown in FIG. 28 only with a difference that the green sub-pixels G are distributed in a different manner. In FIG. 28, four green sub-pixels G also include the green sub-pixels G of two sizes, the green sub-pixels G located in the same row (the same second pixel group 2) have different sizes, and the green sub-pixels G located in the same column (the same fourth pixel group) also have different sizes. The shapes, sizes, and arrangement manner of the red sub-pixel R and the blue sub-pixel B in the first virtual polygon 10 are identical to those shown in FIG. 24, which will not be described redundantly here.

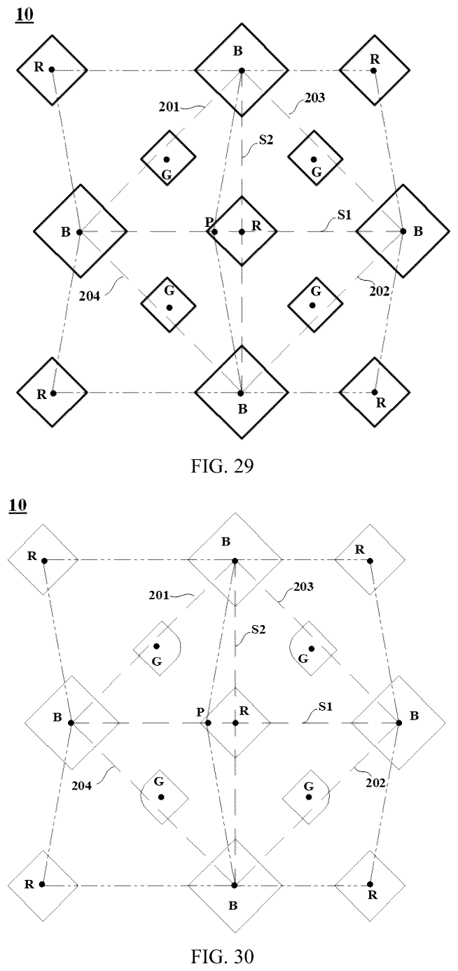

In another example, FIG. 29 is a schematic diagram of another first virtual polygon 10 according to an embodiment of the present disclosure. As shown in FIG. 29, the first virtual polygon 10 has a roughly same pixel distribution with the first virtual polygon 10 shown in FIG. 29 only with a difference that the green sub-pixels G have a different size. In the first virtual polygon 10 shown in FIG. 29, four green sub-pixels G have the same size. The shapes, sizes, and arrangement manner of the red sub-pixel R and the blue sub-pixel B in the first virtual polygon 10 are identical to those shown in FIG. 24, which will not be described redundantly here.

In another example, FIG. 30 is a schematic diagram of another first virtual polygon 10 according to an embodiment of the present disclosure. As shown in FIG. 30, the first virtual polygon 10 has a roughly same pixel distribution with the first virtual polygon 10 shown in FIG. 29 only with a difference that the green sub-pixels G having a different shape, and one angle of the green sub-pixel G in the first virtual polygon 10 is a circular chamfer. As a matter of course, one angle of the green sub-pixel G in the first virtual polygon 10 may also be a flat chamfer. As a matter of course, one edge of the green sub-pixel G may also be cambered, i.e., the green sub-pixel G is fan-shaped. Further, four green sub-pixels G are disposed mirror-symmetrically with S2 as an axis of symmetry. For example, orientations of the circular chamfers of two green sub-pixels G located in the same column are different; the circular chamfers of two green sub-pixels G in one row are disposed oppositely, and the circular chamfers of two green sub-pixels G in another row are disposed facing away from each other. It will be appreciated that the four green sub-pixels G in the first virtual polygon 10 are not limited to the above arrangement manner. In the embodiments of the present disclosure, the orientations of the first angles of adjacent green sub-pixels G located in the same second pixel group 2 are different; the orientations of the first angles of adjacent green sub-pixels G located in the same fourth pixel group 4 are different; and the second sub-pixels G in adjacent fourth pixel groups 4 are axisymmetric graphics to each other with the column direction as an axis of symmetry. For example, the first angle of one of adjacent green sub-pixels G in a second pixel group 2 is oriented leftwards, while the first angle of the other one is oriented rightwards; meanwhile, the first angle of one of adjacent green sub-pixels G in a fourth pixel group 4 is oriented leftwards, while the first angle of the other one is oriented rightwards. Further, the orientations of the first angles of adjacent green sub-pixels G in the same second pixel group 2 are roughly opposite; and the orientations of the first angles of adjacent green sub-pixels G in the same fourth pixel group 4 are roughly opposite. It needs to be noted that “roughly opposite” used here refers to opposite angles of the defining quadrangle corresponding to the green sub-pixels G, where one green sub-pixel G is one opposite angle, and the other green sub-pixel G is the other opposite angle; alternatively, directions of the virtual centers of the two green sub-pixels G to the first angle are roughly opposite directions. For example, a reversely extended line of the connecting line from the virtual center of one green sub-pixel to the first angle is roughly parallel with or has an included angle of less than 30° with the connecting line from the virtual center of the other sub-pixel to the first angle.

The shapes, sizes, and arrangement manner of the red sub-pixel R and the blue sub-pixel B in the first virtual polygon 10 in FIG. 30 are identical to those shown in FIG. 29, which will not be described redundantly here.

In another example, FIG. 31 is a schematic diagram of another first virtual polygon 10 according to an embodiment of the present disclosure. As shown in FIG. 31, the first virtual polygon 10 has a roughly same pixel distribution with the first virtual polygon 10 shown in FIG. 24 only with a difference that the center of the red sub-pixel R is at a different position, where the center of red sub-pixel located within the first virtual polygon 10 is not located at the center of the third virtual quadrangle 200, and the center of the red sub-pixel R is located in S1. If the distances of four green sub-pixels G to the red sub-pixel R are equal, the positions of the green sub-pixels G may be correspondingly adjusted as compared with those in FIG. 24, but the sizes and shapes of the red sub-pixel R, the green sub-pixel G, and the blue sub-pixel B are identical to those of the first virtual polygon 10 shown in FIG. 24, which will not be described redundantly here.

In another example, FIG. 32 is a schematic diagram of another first virtual polygon 10 according to an embodiment of the present disclosure. As shown in FIG. 32, the first virtual polygon 10 has a roughly same pixel distribution with the first virtual polygon 10 shown in FIG. 28 only with a difference that the center of the red sub-pixel R is at a different position, where the center of red sub-pixel located within the first virtual polygon 10 is not located at the center of the third virtual quadrangle 200, and the center of the red sub-pixel R is located in S1. If the distances of four green sub-pixels G to the red sub-pixel R are equal, the positions of the green sub-pixels G may be correspondingly adjusted as compared with those in FIG. 28, but the sizes and shapes of the red sub-pixel R, the green sub-pixel G, and the blue sub-pixel B are identical to those of the first virtual polygon 10 shown in FIG. 28, which will not be described redundantly here.

In another example, FIG. 33 is a schematic diagram of another first virtual polygon 10 according to an embodiment of the present disclosure. As shown in FIG. 33, the first virtual polygon 10 has a roughly same pixel distribution with the first virtual polygon 10 shown in FIG. 29 only with a difference that the center of the red sub-pixel R is at a different position, where the center of red sub-pixel located within the first virtual polygon 10 is not located at the center of the third virtual quadrangle 200, and the center of the red sub-pixel R is located in S1. If the distances of four green sub-pixels G to the red sub-pixel R are equal, the positions of the green sub-pixels G may be correspondingly adjusted as compared with those in FIG. 29, but the sizes and shapes of the red sub-pixel R, the green sub-pixel G, and the blue sub-pixel B are identical to those of the first virtual polygon 10 shown in FIG. 29, which will not be described redundantly here.

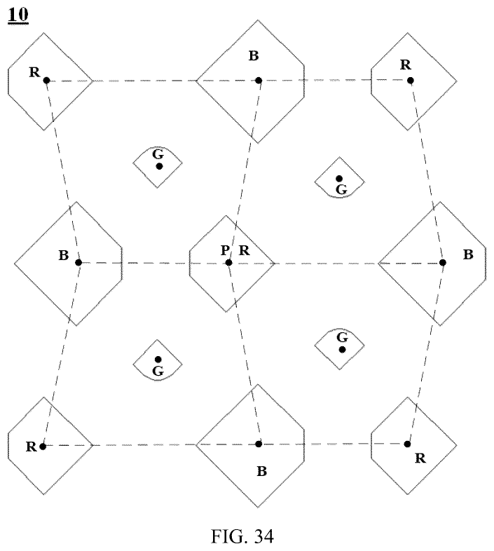

In another example, FIG. 34 is a schematic diagram of another first virtual polygon 10 according to an embodiment of the present disclosure. As shown in FIG. 34, four second virtual quadrangles 100 forming the first virtual polygon 10 are virtual isosceles trapezoids 300. That is, the first virtual point P is located at the virtual center of the red sub-pixel R within the first virtual polygon 10. In particular, the red sub-pixel R, the green sub-pixel G, and the blue sub-pixel B in the first virtual polygon 10 all have the first angles, where both of the first angle of the red sub-pixel R and the first angle of the blue sub-pixel B are flat chamfers, and the green sub-pixel G is fan-shaped. As a matter of course, the first angles of the red sub-pixel R and the blue sub-pixel B may also be circular chamfers, and the green sub-pixel G may also be polygonal with the first angle. FIG. 34 is merely described by taking for example that both of the first angle of the red sub-pixel R and the first angle of the blue sub-pixel B are flat chamfers and the green sub-pixel G is fan-shaped. The pixel array in the embodiments of the present disclosure may be divided into a plurality of fourth virtual quadrangles 400, and any virtual quadrangle includes therebetween two adjacent green sub-pixels G located in the same column (fourth pixel group 4) and two adjacent red sub-pixel R and blue sub-pixel B located in the same row (first pixel group 1). An extension direction of the connecting line of the vertexes of the arcs of two green sub-pixels G within the fourth virtual quadrangle 400 is parallel with the column direction, and the two green sub-pixels G are disposed mirror-symmetrically with the row direction as an axis of symmetry. For example, the first angle of one green sub-pixel G is oriented upwards while the arc of the other green sub-pixel G protrudes downwards. The first angles of the red sub-pixel R and the blue sub-pixel B within the fourth virtual quadrangle 400 are disposed oppositely. The first angle of the red sub-pixel R and the first angle of the blue sub-pixel B within each fourth virtual quadrangle 400 are disposed oppositely. For example, the first angle of the red sub-pixel R is oriented rightwards, and the first angle of the blue sub-pixel B is oriented leftwards. In the embodiments of the present disclosure, the red sub-pixel R, the green sub-pixels G, and the blue sub-pixel B within the fourth virtual quadrangle 400 are disposed in an arrangement manner such that the green sub-pixels G within the fourth virtual quadrangle 400 is close to the red sub-pixel R and the blue sub-pixel B as much as possible. The overall aperture ratio of the pixels can be increased, and the distribution of the green sub-pixels G will be more uniform. Such an arrangement manner may effectively improve the display effect, improve the display sharpness, and reduce the edge jaggedness and the granular sensation of display.

Referring continuously to FIG. 34, the connecting line of the virtual centers of the red sub-pixel R and the blue sub-pixel B located in the same row (first pixel group 1) is roughly in the same straight line, and spacings between the red sub-pixel R and two blue sub-pixels B adjacent thereto are different. For example, the first angle of one red sub-pixel R is opposite to the first angle of one blue sub-pixel B, and the opposite angle to the first angle of the red sub-pixel R may be opposite to the opposite angle to the first angle of the other blue sub-pixel B. In this case, the spacing between the red sub-pixel R and the blue sub-pixel B having opposite first angles is less than the spacing between the red sub-pixel R and the blue sub-pixel B of which the opposite angles to the first angles are opposite. As a matter of course, in the pixel array, the spacings between the blue sub-pixel B and two red sub-pixels R adjacent thereto in the same row may be different. As shown in FIG. 34, the connecting line of the virtual centers of the red sub-pixel R and the blue sub-pixel B located in the same column (third pixel group 3) is not in the same straight line, but the connecting line of the virtual centers of the red sub-pixels R located in the same column may be roughly in the same straight line, and the connecting line of the virtual centers of the blue sub-pixels B located in the same column may be roughly in the same straight line. It should be appreciated that the arrangement manner of the red sub-pixel R and the blue sub-pixel B in the first pixel group 1 is interchangeable with that of the red sub-pixel R and the blue sub-pixel B in the third pixel group 3. That is, the connecting line of the virtual centers of the red sub-pixel R and the blue sub-pixel B located in the same column (third pixel group 3) is roughly in the same straight line, and spacings between the red sub-pixel R and two blue sub-pixels B adjacent thereto are different. The connecting line of the virtual centers of the red sub-pixel R and the blue sub-pixel B located in the same row (first pixel group) is not in the same straight line, but the connecting line of the virtual centers of the red sub-pixels R located in the same column may be roughly in the same straight line, and the connecting line of the virtual centers of the blue sub-pixels B located in the same column may be roughly in the same straight line.

In some embodiments, a shortest distance between the pixel openings of adjacent green sub-pixels G is greater than that between the pixel openings of red sub-pixel R and blue sub-pixel B that are adjacent. The reason for doing so is that the green sub-pixels G are made more compact with the red sub-pixel R and the blue sub-pixel B to improve the overall aperture ratio of the pixels.

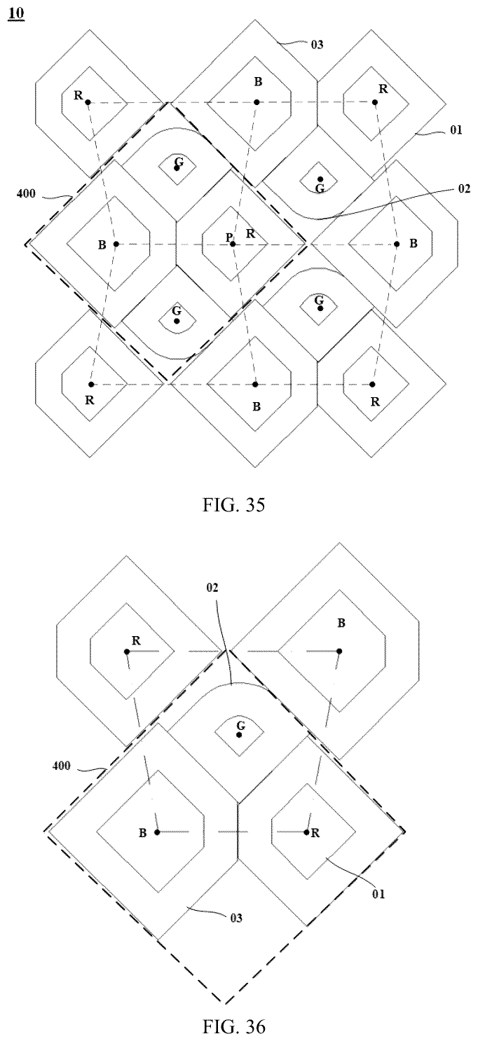

In some embodiments, FIG. 35 is a schematic diagram of light emitting layers of sub-pixels in the first virtual polygon 10 of FIG. 34. As shown in FIG. 35, each sub-pixel has the respective light emitting layer, and the shape of the light emitting layer of each sub-pixel is roughly identical or completely identical to that of each sub-pixel (or the pixel opening of the sub-pixel). That is, the shape of the light emitting layer 01 of the red sub-pixel R is identical to that of the red sub-pixel R; the shape of the light emitting layer 01 of the green sub-pixel G is identical to that of the green sub-pixel G; and the shape of the light emitting layer 03 of the blue sub-pixel B is identical to that of the blue sub-pixel B. The light emitting layer of the green sub-pixel G within each virtual isosceles trapezoid 300 is located within a range defined by the light emitting layers of two red sub-pixels R and the light emitting layers of two blue sub-pixels B located at the positions of the vertex angles of the first virtual isosceles trapezoid. FIG. 36 is a schematic diagram of a distribution of light emitting layers of sub-pixels in a fourth virtual quadrangle 400 in the first virtual polygon of FIG. 34. As shown in FIG. 36, the boundaries of the light emitting layers of the sub-pixels located within the fourth virtual quadrangle 400 are at least partially in contact. Further, the boundary of the light emitting layer 02 of each green sub-pixel G is in contact with the boundaries of the light emitting layer 01 of the red sub-pixel R and the light emitting layer 03 of the blue sub-pixel B that are located within the same virtual isosceles trapezoid 300 and within the same fourth virtual quadrangle 400. In this way, the green sub-pixel G is arranged to be close to the red sub-pixel R and the blue sub-pixel B as much as possible, thus increasing the overall aperture ratio of the pixels and also the distribution of the green sub-pixels G is more uniform.

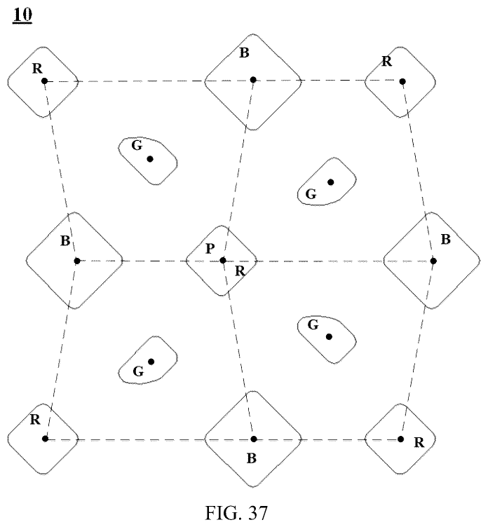

In another example, FIG. 37 is a schematic diagram of another first virtual polygon 10 in an embodiment of the present disclosure. As shown in FIG. 37, the shapes of the red sub-pixel R and the blue sub-pixel B in the first virtual polygon 10 are rectangles (or squares), and the green sub-pixel G is polygonal having the first angle. The first angle of the green sub-pixel may be a flat chamfer or a circular chamfer. FIG. 37 is shown with the case where the first angle of the green sub-pixel G is the circular chamfer as an example. The arrangement manner of the sub-pixels in FIG. 37 is consistent with that in FIG. 35, which will not be described redundantly here.

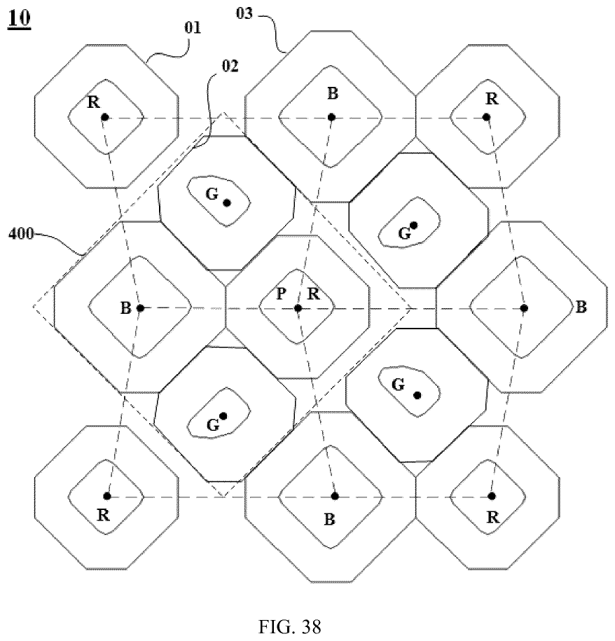

In some embodiments, FIG. 38 is a schematic diagram of light emitting layers of sub-pixels in the first virtual polygon 10 of FIG. 37. As shown in FIG. 38, each sub-pixel has the respective light emitting layer, and the shape of the light emitting layers of respective sub-pixels are identical. That is, the shapes of the light emitting layer 01 of the red sub-pixel R, the light emitting layer 02 of the green sub-pixel G, and the light emitting layer 03 of the blue sub-pixel B are identical. For example, the shape of each light emitting layer is a rectangle (or a square). The light emitting layer 02 of the green sub-pixel G within each virtual isosceles trapezoid is located within a range defined by the light emitting layers 01 of two red sub-pixels R and the light emitting layers 03 of two blue sub-pixels B that are located at the positions of the vertex angles of the first virtual isosceles trapezoid. The boundaries of the light emitting layers of the sub-pixels located within the fourth virtual quadrangle 400 are at least partially in contact. Further, the boundary of the light emitting layer 02 of each green sub-pixel G is in contact with the boundaries of the light emitting layer 01 of the red sub-pixel R and the light emitting layer 03 of the blue sub-pixel B that are located within the same virtual isosceles trapezoid and within the same fourth virtual quadrangle 400. In this way, the green sub-pixel G is arranged to be close to the red sub-pixel R and the blue sub-pixel B as much as possible, thus increasing the overall aperture ratio of the pixels and also causing the distribution of the green sub-pixels G more uniform.

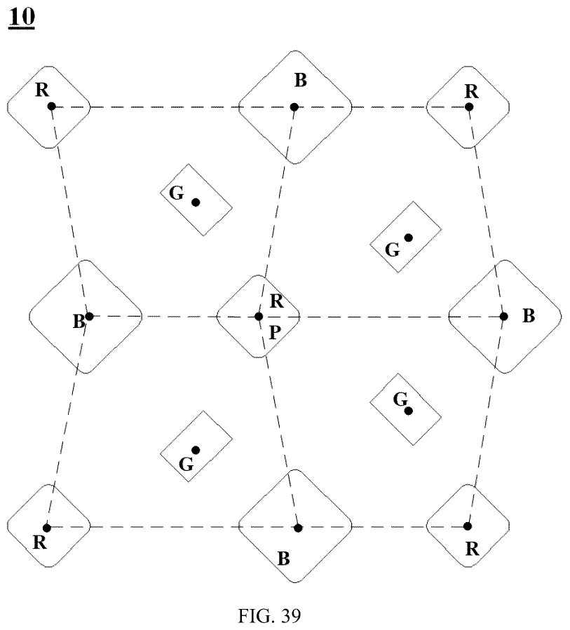

In another example, FIG. 39 is a schematic diagram of another first virtual polygon 10 according to an embodiment of the present disclosure. As shown in FIG. 39, the arrangement manner of the sub-pixels in the first virtual polygon 10 is identical to that of the sub-pixels in FIG. 37 only with a difference that the shapes of the red sub-pixel R and the blue sub-pixel B in the first virtual polygon 10 are rectangles (or squares). The arrangement manner of the sub-pixels in FIG. 39 is consistent with that in FIG. 37, which will not be described redundantly here.

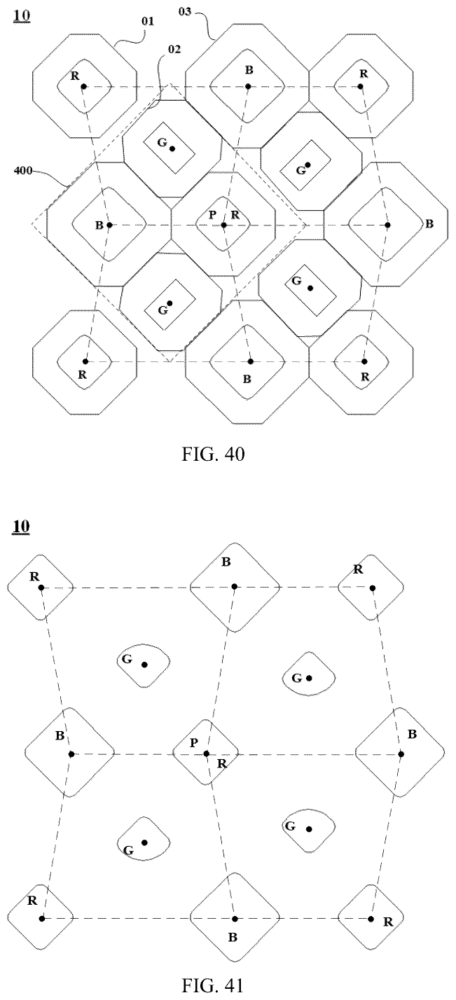

In some embodiments, FIG. 40 is a schematic diagram of light emitting layers of sub-pixels in the first virtual polygon 10 of FIG. 39. As shown in FIG. 40, the shape of the light emitting layer of each sub-pixel is roughly identical or completely identical to that of each sub-pixel (i.e., the pixel opening of each pixel). That is, the shape of the light emitting layer 01 of the red sub-pixel R is identical to that of the red sub-pixel R; the shape of the light emitting layer 01 of the green sub-pixel G is identical to that of the green sub-pixel G; and the shape of the light emitting layer 03 of the blue sub-pixel B is identical to that of the blue sub-pixel B. The arrangement manner of the light emitting layers of the sub-pixels is identical to that of the light emitting layers in FIG. 38, which will not be described redundantly here.

In another example, FIG. 41 is a schematic diagram of another first virtual polygon 10 according to an embodiment of the present disclosure. As shown in FIG. 41, the arrangement manner of the sub-pixels in the first virtual polygon 10 is identical to that of the sub-pixels in FIG. 39 only with a difference that the green sub-pixel G in the first virtual polygon 10 is fan-shaped. The arrangement manner of the sub-pixels in FIG. 41 is consistent with that in FIG. 39, which will not be described redundantly here.

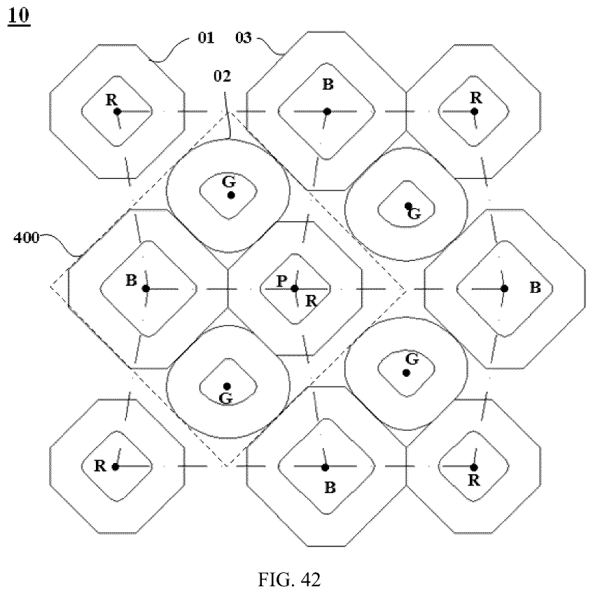

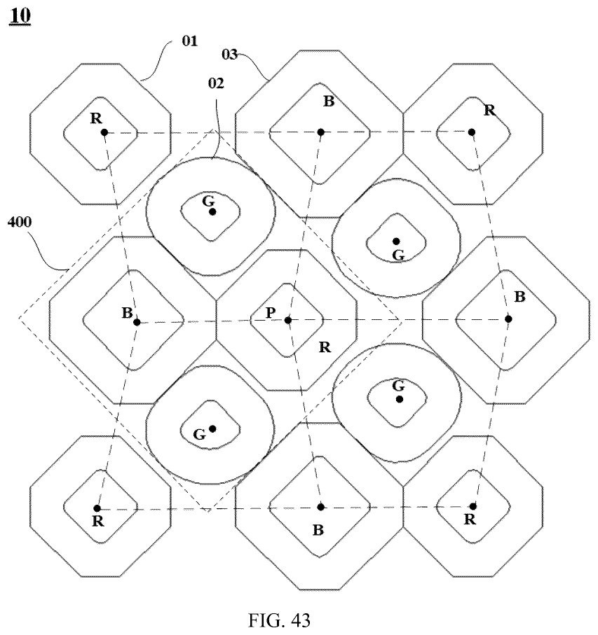

In some embodiments, FIG. 42 is a schematic diagram of light emitting layers of sub-pixels in the first virtual polygon 10 of FIG. 41. As shown in FIG. 42, the shape of the light emitting layer of each sub-pixel is roughly identical or completely identical to that of each sub-pixel (i.e., the pixel opening of each pixel). That is, the shape of the light emitting layer 01 of the red sub-pixel R is identical to that of the red sub-pixel R; the shape of the light emitting layer 01 of the green sub-pixel G is identical to that of the green sub-pixel G; and the shape of the light emitting layer 03 of the blue sub-pixel B is identical to that of the blue sub-pixel B. In this case, the light emitting layer 01 of the green sub-pixel G within each virtual isosceles trapezoid is located within a range defined by the light emitting layers 01 of two red sub-pixels R and the light emitting layers 03 of two blue sub-pixels B that are located at the positions of the vertex angles of the first virtual isosceles trapezoid, and the boundaries of the sub-pixels located within the fourth virtual quadrangle are in contact.

In some embodiments, FIG. 43 is another schematic diagram of light emitting layers of sub-pixels in the first virtual polygon 10 of FIG. 41. As shown in FIG. 43, the shape of the light emitting layer of each sub-pixel is roughly identical or completely identical to that of each sub-pixel (i.e., the pixel opening of each pixel). That is, the shape of the light emitting layer 01 of the red sub-pixel R is identical to that of the red sub-pixel R; the shape of the light emitting layer 01 of the green sub-pixel G is identical to that of the green sub-pixel G; and the shape of the light emitting layer 03 of the blue sub-pixel B is identical to that of the blue sub-pixel B. In this case, the light emitting layer of the green sub-pixel G within each virtual isosceles trapezoid is located within a range defined by the light emitting layers 01 of two red sub-pixels R and the light emitting layers 03 of two blue sub-pixels B that are located at the positions of the vertex angles of the first virtual isosceles trapezoid, and the boundary of the light emitting layer 02 of the green sub-pixel G is in contact with the boundaries of the light emitting layers 03 of two blue sub-pixels B.

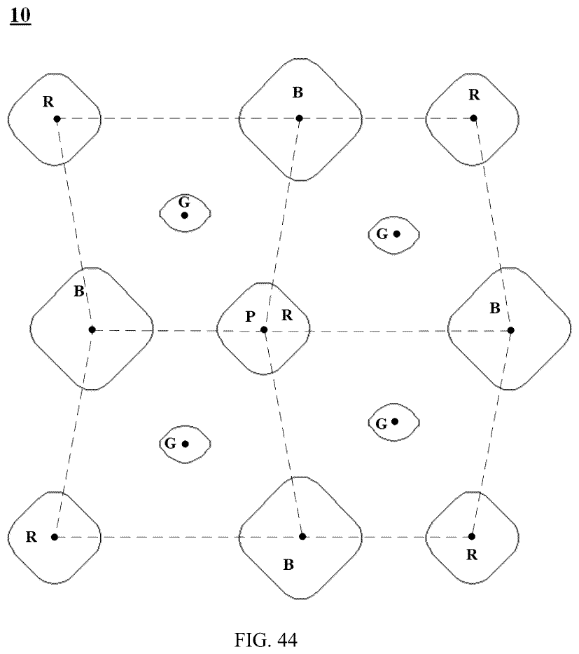

In another example, FIG. 44 is a schematic diagram of another first virtual polygon 10 according to an embodiment of the present disclosure. As shown in FIG. 44, the arrangement manner of the sub-pixels in the first virtual polygon 10 is identical to that of the sub-pixels in FIG. 41 only with a difference that the green sub-pixel G in the first virtual polygon 10 is elliptical. The arrangement manner of the sub-pixels in FIG. 44 is consistent with that in FIG. 41, which will not be described redundantly here.

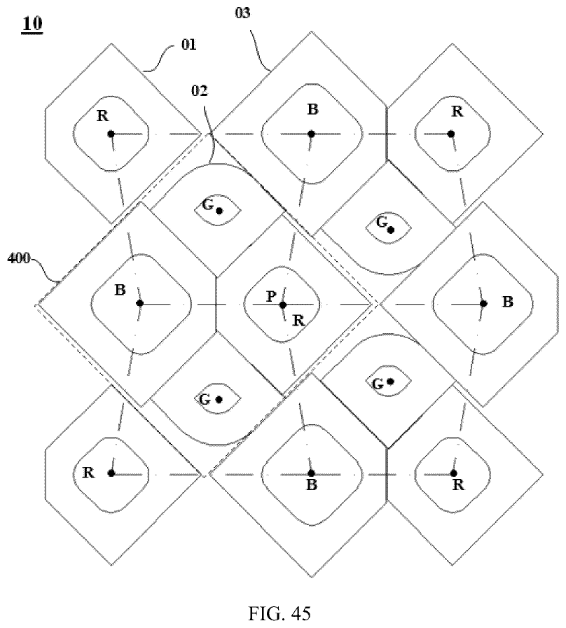

In some embodiments, FIG. 45 is a schematic diagram of light emitting layers of sub-pixels in the first virtual polygon 10 of FIG. 44. As shown in FIG. 45, the shape of the light emitting layer of each sub-pixel is different from that of the sub-pixel corresponding thereto. For example, the shape of the light emitting layer of each sub-pixel is identical to that of the light emitting layer in FIG. 45, and the arrangement manner of the light emitting layers of the sub-pixels is also identical to that of the light emitting layers in FIG. 35, which will not be described redundantly here.

In an embodiment of the present disclosure, by adjusting the positional relationship of the red sub-pixel R, the green sub-pixel G, and the blue sub-pixel B and adjusting the shapes and the sizes of the red sub-pixel R, the green sub-pixel G, and the blue sub-pixel B and the shapes and the sizes of the light emitting layers, the display effect of a display panel employing the pixel array in the embodiments of the present disclosure can be better; the display sharpness can be improved; and the edge jaggedness and the granular sensation of display can be reduced.

In another aspect, an embodiment of the present disclosure further provides a display apparatus, including any pixel array described above provided by the embodiments of the present disclosure. The display apparatus may be any product or component with a display function, such as a mobile phone, a tablet computer, a television, a display, a notebook computer, a digital photo frame, and a navigator.

At least one embodiment of the present disclosure further provides a display apparatus, including any touch display panel described above.

For example, in an embodiment of the present disclosure, the first touch layer M1 may be made of a metal material, and the second touch layer M2 may be made of a metal material. For example, the metal includes at least one of titanium and aluminum. In some embodiments, a component in the first touch layer M1 is of a structure having three sub-layers Ti—Al—Ti, and a component in the second touch layer M2 is of a structure having three sub-layers: a first touch sub-layer, a second touch sub-layer, and a third touch sub-layer (Ti—Al—Ti), the first touch sub-layer being closer to the base substrate than the third touch sub-layer. For example, a thickness of the first touch sub-layer is less than that of the second touch sub-layer, and a thickness of the third touch sub-layer is less than that of the second touch sub-layer. In some embodiments, the thickness of the first touch sub-layer is about 300 angstroms, the thickness of the second touch sub-layer is about 4000 angstroms, and the thickness of the third touch sub-layer is about 300 angstroms, without limitation thereto.

For example, the base substrate may be made of an insulating material. The base substrate may be, but not limited to, a flexible substrate. For example, the material of the base substrate includes polyimide.

For example, a thickness of at least one of the first insulating layer 11, the second insulating layer 12, the third insulating layer 13, and the capping layer 14 ranges from 15000 angstroms to 20000 angstroms, without limitation thereto.

For example, the thickness of the third insulating layer 13 is greater than that of the second insulating layer 12 and greater than that of the first insulating layer 11. For example, the thicknesses of the first insulating layer 11 and the second insulating layer 12 may be roughly equal.

For example, the display apparatus includes an OLED or a product including an OLED. For example, the display apparatus may be any product or component with the display function and including the touch display panel described above, such as a television, a digital camera, a mobile phone, a watch, a tablet computer, a notebook computer, and a navigator.

It should be noted that, for the sake of clarity, in the drawings used to describe the embodiments of the present disclosure, the thickness of a layer or region is exaggerated. It can be understood that in a case where an element such as a layer, film, region, or substrate is referred to as being “on” or “under” another element, the element can be “directly” “on” or “under” the other element, or there may be intermediate elements.

Moreover, in case of no conflict, features(s) in the same embodiment or in different embodiments of the present disclosure may be combined with each other.

What have been described above are only specific implementations of the present disclosure, the protection scope of the present disclosure is not limited thereto. Any changes or substitutions easily occur to those skilled in the art within the technical scope of the present disclosure should be covered in the protection scope of the present disclosure. Therefore, the protection scope of the present disclosure should be based on the protection scope of the claims.

1. A touch structure, comprising:
a first insulating layer;
a first touch layer located on the first insulating layer;
a second insulating layer located on a side of the first touch layer facing away from the first insulating layer; and
a second touch layer located on a side of the second insulating layer facing away from the first touch layer,
wherein the first touch layer comprises a plurality of first touch electrodes and a plurality of first touch lines;
the second touch layer comprises a plurality of second touch electrodes and a plurality of second touch lines;
the plurality of first touch electrodes and the plurality of second touch electrodes are intersected with each other and are insulated from each other;
each of the plurality of first touch electrodes is of a mesh structure, and each of the plurality of second touch electrodes is of the mesh structure;
mesh lines of two adjacent first touch electrodes are disconnected and mesh lines of two adjacent second touch electrodes are disconnected; and no via hole is arranged in a region of the second insulating layer that corresponds to the plurality of first touch electrodes and the plurality of second touch electrodes.

2. The touch structure according to claim 1, wherein the second touch layer further comprises a third touch line and the first touch layer further includes a fourth touch line, the third touch line and the first touch line are connected through a first via hole passing through the second insulating layer to form a first lead, and the fourth touch line and the second touch line are connected through a second via hole passing through the second insulating layer to form a second lead.

3. The touch structure according to claim 2, wherein the first via hole and the second via hole are located in a periphery of an effective region in which the plurality of first touch electrodes and the plurality of second touch electrodes are disposed, and
the touch structure further comprises a ground line, wherein the ground line is grounded, and the ground line is located between the first lead and the second lead at a position close to a bonding region.

4. The touch structure according to claim 1, wherein the first touch layer further comprises a plurality of first dummy electrodes, each of the plurality of first dummy electrodes and the first touch electrode are insulated from each other, the second touch layer further comprises a plurality of second dummy electrodes, each of the plurality of second dummy electrodes and the second touch electrode are insulated from each other,
the first dummy electrode comprises a plurality of first dummy sub-electrodes and the second dummy electrode comprises a plurality of second dummy sub-electrodes, the plurality of first dummy sub-electrodes are spaced apart from each other, and the plurality of second dummy sub-electrodes are spaced apart from each other,
the first dummy electrode is of the mesh structure, and a mesh line of the first touch electrode is disconnected from a mesh line of the first dummy electrode, and the second dummy electrode is of the mesh structure, and a mesh line of the second touch electrode is disconnected from a mesh line of the second dummy electrode.

5. The touch structure according to claim 1, wherein the first touch electrode comprises a plurality of first touch portions that are connected to each other, and the second touch electrode comprises a plurality of second touch portions that are connected to each other.

6. The touch structure according to claim 5, wherein the first touch layer further comprises a plurality of third dummy electrodes and the second touch layer further comprises a plurality of fourth dummy electrodes, each of the plurality of third dummy electrodes is located between two adjacent first touch portions of the first touch electrode, and each of the plurality of fourth dummy electrodes is located between two adjacent second touch portions of the second touch electrode,
the third dummy electrode comprises a plurality of third dummy sub-electrodes and the fourth dummy electrode comprises a plurality of fourth dummy sub-electrodes, the plurality of third dummy sub-electrodes are spaced apart from each other, and the plurality of fourth dummy sub-electrodes are spaced apart from each other.

7. The touch structure according to claim 1, further comprising a third insulating layer, wherein the third insulating layer is located on a side of the second touch layer facing away from the second insulating layer, and
at least two of the first insulating layer, the second insulating layer, and the third insulating layer comprise an organic layer.

8. The touch structure according to claim 1, wherein one of the first touch electrode and the second touch electrode extends in a first direction, the other one of the first touch electrode and the second touch electrode extends in a second direction, and the first direction intersects the second direction,
the first touch electrode is connected to at least one of the plurality of first touch lines, and the first touch electrode and the first touch line connected thereto are of an integrated structure, the second touch electrode is connected to at least one of the plurality of second touch lines, and the second touch electrode and the second touch line connected thereto are of an integrated structure.

9. A touch display panel, comprising a display structure and a touch structure,
wherein the display structure comprises a plurality of sub-pixels that comprise a plurality of light emitting elements;
the touch structure comprises:
a first insulating layer;
a first touch layer located on the first insulating layer;
a second insulating layer located on a side of the first touch layer facing away from the first insulating layer; and
a second touch layer located on a side of the second insulating layer facing away from the first touch layer,
wherein the first touch layer comprises a plurality of first touch electrodes and a plurality of first touch lines;
the second touch layer comprises a plurality of second touch electrodes and a plurality of second touch lines;
the plurality of first touch electrodes and the plurality of second touch electrodes are intersected with each other and are insulated from each other;
each of the plurality of first touch electrodes is of a mesh structure, and each of the plurality of second touch electrodes is of the mesh structure;
mesh lines of two adjacent first touch electrodes are disconnected and mesh lines of two adjacent second touch electrodes are disconnected, and no via hole is arranged in a region of the second insulating layer that corresponds to the plurality of first touch electrodes and the plurality of second touch electrodes.

10. The touch display panel according to claim 9, further comprising:
a base substrate; and
an encapsulation layer,
wherein the encapsulation layer is located on a side of the plurality of light emitting elements facing away from the base substrate, and configured to encapsulate the plurality of light emitting elements; and the touch structure is located on a side of the encapsulation layer facing away from the plurality of light emitting elements.

11. The touch display panel according to claim 10, further comprising an anti-reflection layer, wherein the anti-reflection layer is located on a side of the touch structure facing away from the base substrate.

12. The touch display panel according to claim 11, wherein the anti-reflection layer comprises a black matrix, orthographic projections of the plurality of first touch electrodes and the plurality of second touch electrodes on the base substrate overlap an orthographic projection of the black matrix on the base substrate.

13. The touch display panel according to claim 12, wherein the anti-reflection layer comprises a color filter layer that comprises a plurality of color filter units, and an orthographic projection of the plurality of color filter units on the base substrate does not overlap the orthographic projections of the plurality of first touch electrodes and the plurality of second touch electrodes on the base substrate.

14. The touch display panel according to claim 10, further comprising a pixel definition layer, wherein the pixel definition layer comprises a plurality of openings and a pixel definition portion located between two adjacent openings, and the orthographic projections of the plurality of first touch electrodes and the plurality of second touch electrodes on the base substrate overlap an orthographic projection of the pixel definition portion on the base substrate.

15. The touch display panel according to claim 14, wherein distances of an orthographic projection of at least a portion of mesh lines in the plurality of first touch electrodes and the plurality of second touch electrodes on the base substrate from orthographic projections of two opposite edges of the pixel definition portion on the base substrate are equal or substantially equal.

16. The touch display panel according to claim 12, wherein distances of the orthographic projection of at least a portion of the mesh lines in the plurality of first touch electrodes and the plurality of second touch electrodes on the base substrate from orthographic projections of two opposite edges of the black matrix on the base substrate are equal or substantially equal.

17. The touch display panel according to claim 9, wherein the plurality of sub-pixels comprise a first sub-pixel, two second sub-pixels, and a third sub-pixel, and the two second sub-pixels are arranged in a first direction, the first sub-pixel and the third sub-pixel are arranged in a second direction, the first direction intersects the second direction, and the mesh lines comprise a portion located among the first sub-pixel, the two second sub-pixels, and the third sub-pixel and extending in the first direction.

18. The touch display panel according to claim 17, wherein a length of the portion of the mesh lines that extends in the first direction is less than a maximum length of a light emitting region of the first sub-pixel in the first direction and less than a maximum length of a light emitting region of the third sub-pixel in the first direction.

19. The touch display panel according to claim 9, wherein each of the plurality of sub-pixels has a virtual pixel center, an extension direction of a width and an extension direction of a length of the sub-pixel are taken as a width extension direction and a length extension direction of a defining quadrangle, respectively, and the width and the length of the sub-pixel are taken as a width and a length of the defining quadrangle, respectively, and an intersection point of diagonals of the defining quadrangle is taken as the virtual pixel center, the plurality of sub-pixels comprise a first sub-pixel, second sub-pixels, and a third sub-pixel, the first sub-pixel and the third sub-pixel are arranged alternately in the first direction to form a first pixel group, the second sub-pixels are disposed side by side in the first direction to form a second pixel group, the first sub-pixel and the third sub-pixel are arranged alternately in the second direction to form a third pixel group, the second sub-pixels are disposed side by side in the second direction to form a fourth pixel group, the first pixel group and the second pixel group are arranged alternately in the second direction, and the third pixel group and the fourth pixel group are arranged alternately in the first direction,
wherein sequential connecting lines of virtual centers of two first sub-pixels and two third sub-pixels between two adjacent first pixel groups and two adjacent third pixel groups form a second virtual quadrangle, four second virtual quadrangles arranged in an array form a first virtual polygon in such a manner that adjacent edges are shared, and the first sub-pixels and the third sub-pixels are located at vertex angles or edges of the first virtual polygon and alternately distributed clockwise at the vertex angles or the edges of the first virtual polygon,
the first virtual polygon has a first virtual point therein, and connecting lines of the first virtual point and the virtual centers of four third sub-pixels on the first virtual polygon divide the first virtual polygon into four virtual isosceles trapezoids.

20. A display apparatus, comprising the touch display panel according to claim 9.
